(19) United States
(12) Patent Application Publication
(10) Pub. No.: US 2026/0113941 A1
(43) Pub. Date: Apr. 23, 2026

(54) METHOD OF MANUFACTURING A SEMICONDUCTOR MEMORY DEVICE

(71) Applicant: SK hynix Inc., Icheon-si Gyeonggi-do (KR)

(72) Inventors: Won Geun CHOI, Icheon-si Gyeonggi-do (KR); Jung Shik JANG, Icheon-si Gyeonggi-do (KR); Rho Gyu KWAK, Icheon-si Gyeonggi-do (KR); Mi Seong PARK, Icheon-si Gyeonggi-do (KR); In Su PARK, Icheon-si Gyeonggi-do (KR); Na Yeong YANG, Icheon-si Gyeonggi-do (KR); Seok Min CHOI, Icheon-si Gyeonggi-do (KR)

(73) Assignee: SK hynix Inc., Icheon-si Gyeonggi-do (KR)

(21) Appl. No.: 19/180,869

(22) Filed: Apr. 16, 2025

(30) Foreign Application Priority Data
Oct. 22, 2024 (KR) 10-2024-0144745

(51) Int. Cl. H10B 43/27; H10B 43/10

(52) U.S. Cl. CPC H10B 43/27; H10B 43/10

(57) ABSTRACT

A method of manufacturing a semiconductor memory device includes: forming a hole passing through at least a portion of a stacked structure having alternately stacked first material layers and second material layers; sequentially forming a blocking insulating layer, a charge trap layer, and a tunnel insulating layer the hole; forming a preliminary channel layer along the tunnel insulating layer; forming a sacrificial layer by oxidizing an exposed inner wall of the preliminary channel layer; forming a first sacrificial layer and a second sacrificial layer separated in a second direction crossing to a first direction by patterning the sacrificial layer; and forming a first channel layer and a second channel layer by separating the preliminary channel layer in the second direction by performing an etching process.

### CROSS-REFERENCE TO RELATED APPLICATION

The present application claims priority under 35 U.S.C. § 119(a) to Korean patent application number 10-2024-0144745 filed on Oct. 22, 2024, in the Korean Intellectual Property Office, the entire disclosure of which application is incorporated herein by reference.

### BACKGROUND

### 1. Technical Field

Various embodiments of the present disclosure generally relate to an electronic device, and more particularly, to a method of manufacturing a semiconductor memory device.

### 2. Related Art

Nonvolatile memory devices are memory devices in which stored data are retained even when supplied power is interrupted. As the improvement in integration of a two-dimensional (2D) nonvolatile memory devices in which memory cells are formed as a single layer on a substrate reaches its limit, three-dimensional (3D) nonvolatile memory devices in which memory cells are stacked in a vertical direction on a substrate are being proposed.

A 3D nonvolatile memory device may include interlayer insulating layers and gate electrodes that are alternately stacked, and channel layers penetrating the interlayer insulating layers and the gate electrodes, with memory cells stacked along the channel layers. To improve the operational reliability of such a nonvolatile memory device having a 3D structure, various structures and manufacturing methods have been developed.

### SUMMARY

Various embodiments of the present disclosure may be directed to a semiconductor memory device that includes a vertical structure including a plurality of plug patterns and a method of manufacturing the semiconductor memory device.

In accordance with an embodiment of the present disclosure, a method of manufacturing a semiconductor memory device may include: forming a hole passing through at least a portion of a stacked structure in which first material layers and second material layers are alternately stacked in a first direction; forming a blocking insulating layer along the hole; forming a charge trap layer along the blocking insulating layer; forming a tunnel insulating layer along the charge trap layer; forming a preliminary channel layer along the tunnel insulating layer; forming a sacrificial layer by oxidizing an exposed inner wall of the preliminary channel layer; forming a first sacrificial layer and a second sacrificial layer that are separated from each other in a second direction crossing to the first direction by patterning the sacrificial layer; and forming a first channel layer and a second channel layer by separating the preliminary channel layer in the second direction by performing an etching process.

In accordance with an embodiment of the present disclosure, a method of manufacturing a semiconductor memory device may include: forming a hole passing through at least a portion of a stacked structure in which first material layers and second material layers are alternately stacked in a first direction; forming a blocking insulating layer along the hole; forming a charge trap layer along the blocking insulating layer; forming a tunnel insulating layer along the charge trap layer; forming a preliminary channel layer along the tunnel insulating layer; etching the preliminary channel layer to a decreased thickness; forming a sacrificial layer by oxidizing an inner wall of the preliminary channel layer; forming a first sacrificial layer and a second sacrificial layer that are separated from each other in a second direction crossing to the first direction by patterning the sacrificial layer; and forming a first channel layer and a second channel layer by separating the preliminary channel layer in the second direction by performing an etching process.

In accordance with an embodiment of the present disclosure, a method of manufacturing a semiconductor memory device may include: forming a hole passing through at least a portion of a stacked structure in which first material layers and second material layers are alternately stacked in a first direction; forming recess regions by etching the second material layers through the hole to a recessed depth; forming a blocking insulating layer and a charge trap layer in each of the recess regions; forming a tunnel insulating layer along the first material layers and a sidewall of the charge trap layer; forming a preliminary channel layer along the tunnel insulating layer; forming a sacrificial layer by oxidizing an inner wall of the preliminary channel layer; forming a first sacrificial layer and a second sacrificial layer that are separated from each other in a second direction crossing to the first direction by patterning the sacrificial layer; and forming a first channel layer and a second channel layer by separating the preliminary channel layer in the second direction by performing an etching process k.

In accordance with an embodiment of the present disclosure, a method of manufacturing a semiconductor memory device may include: forming a hole passing through at least a portion of a stacked structure in which first material layers and second material layers are alternately stacked in a first direction; forming recess regions by etching the second material layers exposed through the hole to a recessed depth; forming a blocking insulating layer and a charge trap layer in each of the recess regions; forming a tunnel insulating layer along the first material layers and the charge trap layer; forming a preliminary channel layer along the tunnel insulating layer; etching the preliminary channel layer to decrease a thickness of the preliminary channel layer; forming a sacrificial layer by oxidizing an exposed inner wall of the preliminary channel layer; forming a first sacrificial layer and a second sacrificial layer that are separated from each other in a second direction orthogonal to the first direction by patterning the sacrificial layer; and forming a first channel layer and a second channel layer by separating the preliminary channel layer in the second direction by performing an etching process.

### BRIEF DESCRIPTION OF THE DRAWINGS

FIG. 1 is a block diagram illustrating a semiconductor memory device according to an embodiment of the present disclosure.

FIG. 2 is a circuit diagram of a memory cell array according to an embodiment of the present disclosure.

FIGS. 3A and 3B are views illustrating the vertical arrangement of a semiconductor memory device according to embodiments of the present disclosure.

FIGS. 4A, 4B, and 4C are a plan view and sectional views for describing a semiconductor memory device according to an embodiment of the present disclosure.

FIGS. 5A, 5B, 5C, 6A, 6B, 6C, 7, 8, 9, 10A, 10B, 10C, 11A, 11B, and 11C are plan views and sectional views for describing a method of manufacturing a semiconductor memory device according to an embodiment of the present disclosure.

FIGS. 12A, 12B, 12C, 13A, 13B, 13C, 14, 15, 16, 17A, 17B, 17C, 18A, 18B, and 18C are plan views and sectional views for describing a method of manufacturing a semiconductor memory device according to an embodiment of the present disclosure.

FIGS. 19A, 19B, and 19C are a plan view and sectional views for describing a semiconductor memory device according to an embodiment of the present disclosure.

FIGS. 20A, 20B, 20C, 21A, 21B, 21C, 22, 23, 24, 25A, 25B, 25C, 26A, 26B, and 26C are plan views and sectional views for describing a method of manufacturing a semiconductor memory device according to an embodiment of the present disclosure.

FIGS. 27A, 27B, 27C, 28A, 28B, 28C, 29, 30, 31, 32A, 32B, 32C, 33A, 33B, and 33C are plan views and sectional views for describing a method of manufacturing a semiconductor memory device according to an embodiment of the present disclosure.

FIG. 34 is a block diagram illustrating a memory system including a semiconductor memory device according to an embodiment of the present disclosure.

### DETAILED DESCRIPTION

Specific structural or functional descriptions of embodiments according to the concept of the present disclosure, disclosed in the present specification or application, are exemplified to describe the embodiments according to the concept of the present disclosure. The embodiments according to the concept of the present disclosure should not be construed as being limited to embodiments described in the present specification or application, and may be modified in various forms and replaced with other equivalent embodiments.

Hereinafter, although terms such as “first” and “second” may be used herein to describe various elements, the elements are not limited by these terms. The terms are used to distinguish one component from another component, and the order or number of the components is not limited by the terms.

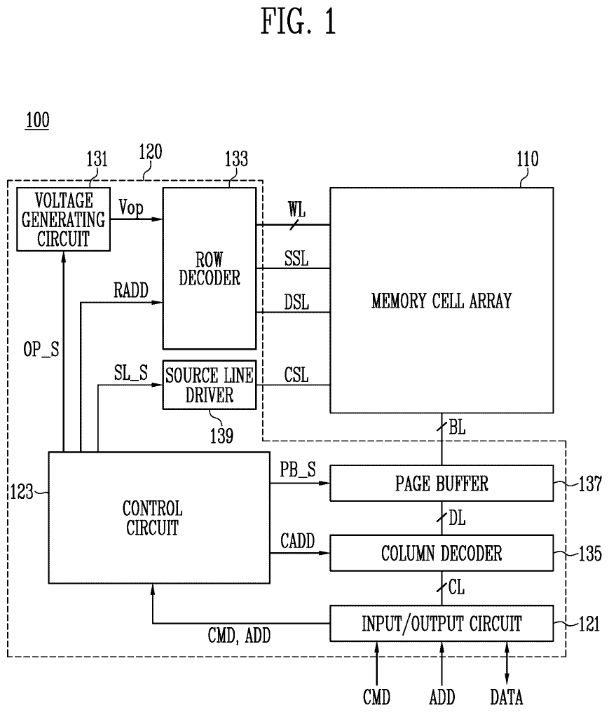

FIG. 1 is a block diagram illustrating a semiconductor memory device according to an embodiment of the present disclosure.

Referring to FIG. 1, a semiconductor memory device 100 may include a peripheral circuit 120 and a memory cell array 110.

The peripheral circuit 120 may perform a program operation of storing data in the memory cell array 110, a read operation of outputting data stored in the memory cell array 110, and an erase operation of erasing data stored in the memory cell array 110. In an embodiment, the peripheral circuit 120 may include an input/output circuit 121, a control circuit 123, a voltage generating circuit 131, a row decoder 133, a column decoder 135, a page buffer 137, and a source line driver 139.

The peripheral circuit 120 may be connected to the memory cell array 110 through a common source line CSL, bit lines BL, a drain select line DSL, word lines WL, and a source select line SSL.

The input/output circuit 121 may transfer a command CMD and an address ADD, received from an external device (e.g., a memory controller) of the semiconductor memory device 100, to the control circuit 123. The input/output circuit 121 may exchange data DATA with the external device and the column decoder 135.

The control circuit 123 may output an operation signal OP_S, a row address RADD, a source line control signal SL_S, a page buffer control signal PB_S, and a column address CADD in response to the command CMD and the address ADD.

The voltage generating circuit 131 may generate various operating voltages Vop that are used for a program operation, a read operation, and an erase operation in response to the operation signal OP_S.

The row decoder 133 may transfer the operating voltages Vop to the drain select line DSL, the word lines WL, and the source select line SSL in response to the row address RADD.

The column decoder 135 may transmit the data DATA, input from the input/output circuit 121, to the page buffer 137 or transmit data DATA, stored in the page buffer 137, to the input/output circuit 121 in response to the column address CADD. The column decoder 135 may exchange data DATA with the input/output circuit 121 through column lines CL. The column decoder 135 may exchange data DATA with the page buffer 137 through data lines DL.

The page buffer 137 may store read data, received through the bit lines BL, in response to the page buffer control signal PB_S. The page buffer 137 may sense the voltages or currents of the bit lines BL during a read operation.

The source line driver 139 may control a voltage that is applied to the common source line CSL in response to the source line control signal SL_S.

The memory cell array 110 may include a plurality of memory blocks. Each of the memory blocks may include a plurality of memory cells arranged in a three-dimensional (3D) form. The plurality of memory cells may be divided into a plurality of memory cell strings. Each memory cell may be a nonvolatile memory cell. In an embodiment, each memory cell may be a NAND flash memory cell.

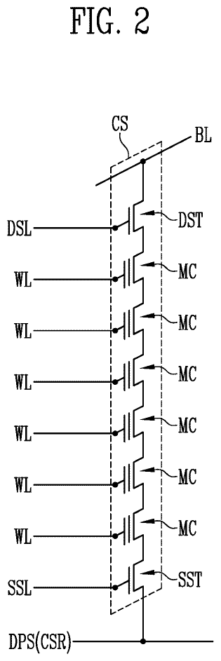

FIG. 2 is a circuit diagram of a memory cell array according to an embodiment of the present disclosure.

Referring to FIG. 2, a memory cell string CS of the memory cell array may include at least one source select transistor SST, a plurality of memory cells MC, and at least one drain select transistor DST. The plurality of memory cells MC may be connected in series between the source select transistor SST and the drain select transistor DST. The source select transistor SST, the plurality of memory cells MC, and the drain select transistor DST may be connected in series by a channel pattern or a channel layer. The channel pattern or the channel layer may be used as a channel region of the memory cell string CS, and it may be formed of a semiconductor layer.

A common source region CSR and a bit line BL may be connected to the channel pattern or channel layer of the memory cell string CS. A voltage for discharging the potential of the channel region of the memory cell string CS may be applied to the common source region CSR. A voltage for precharging the channel region of the memory cell string CS may be applied to the bit line BL.

The plurality of memory cells MC of the memory cell string CS may be connected to the common source region CSR via the source select transistor SST. The plurality of memory cells MC of the memory cell string CS may be connected to the bit line BL via the drain select transistor DST.

Gate electrodes of the source select transistor SST, the plurality of memory cells MC, and the drain select transistor DST may form a gate stacked structure. The gate stacked structure may include a source select line SSL provided as the gate electrode of the source select transistor SST, a plurality of word lines WL provided as the plurality of gate electrodes of the plurality of memory cells MC, and a drain select line DSL provided as the gate electrode of the drain select transistor DST.

The common source region CSR may be electronically connected to the common source line CSL illustrated in FIG. 1. The common source region CSR may be formed in a doped semiconductor structure DPS.

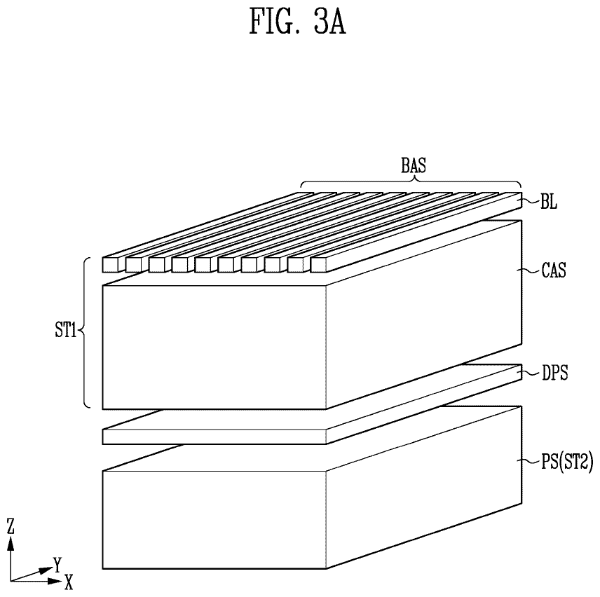

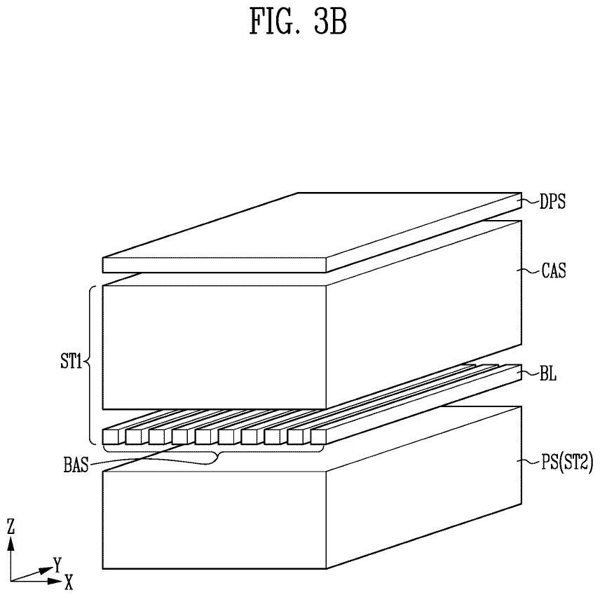

FIGS. 3A and 3B are views illustrating the vertical arrangement of a semiconductor memory device according to embodiments of the present disclosure.

Referring to FIGS. 3A and 3B, the semiconductor memory device may include a first structure ST1, a second structure ST2, and a doped semiconductor structure DPS. The first structure ST1 may include a cell array structure CAS and a bit line array structure BAS, and the second structure ST2 may include a peripheral circuit structure PS.

The bit line array structure BAS may include the bit lines BL described above with reference to FIGS. 1 and 2.

The cell array structure CAS may be between the bit line array structure BAS and the doped semiconductor structure DPS. The cell array structure CAS may include a plurality of gate electrodes connected to a plurality of memory cell strings. The plurality of gate electrodes may include the source select line SSL, the plurality of word lines WL, and the drain select line DSL, illustrated in FIG. 2, and they may be spaced apart from each other in a vertical direction. The cell array structure CAS may include a channel pattern (or a channel layer) penetrating the plurality of gate electrodes. The plurality of gate electrodes and the channel pattern (or channel layer) may be formed in various structures to improve the degree of integration of memory cell strings.

The doped semiconductor structure DPS may include at least one of n-type impurities and p-type impurities. The doped semiconductor structure DPS may include an n-type impurity region provided as the common source region CSR illustrated in FIG. 2. The present disclosure is not limited thereto, and the doped semiconductor structure DPS may further include a p-type impurity region as a well region.

The peripheral circuit structure PS may include a region overlapped by the doped semiconductor structure DPS, the cell array structure CAS, and the bit line array structure BAS. The peripheral circuit structure PS may include a plurality of transistors, a capacitor, a resistor, and the like, which constitute the peripheral circuit 120 illustrated in FIG. 1.

The peripheral circuit structure PS may be adjacent to the doped semiconductor structure DPS, as illustrated in FIG. 3A, or may be adjacent to the bit line array structure BAS, as illustrated in FIG. 3B.

Although not illustrated in the drawings, each of the first structure ST1 and the second structure ST2 may include at least one of a plurality of interconnections, a plurality of contacts, and a plurality of conductive bonding pads used for electrical connection.

The first structure ST1, the doped semiconductor structure DPS, and the second structure ST2 may be stacked in a vertical direction (Z). Further, the bit lines BL may be sequentially arranged in a first horizontal direction (X), and each of the bit lines BL may extend in a second horizontal direction (Y) orthogonal to the first horizontal direction (X).

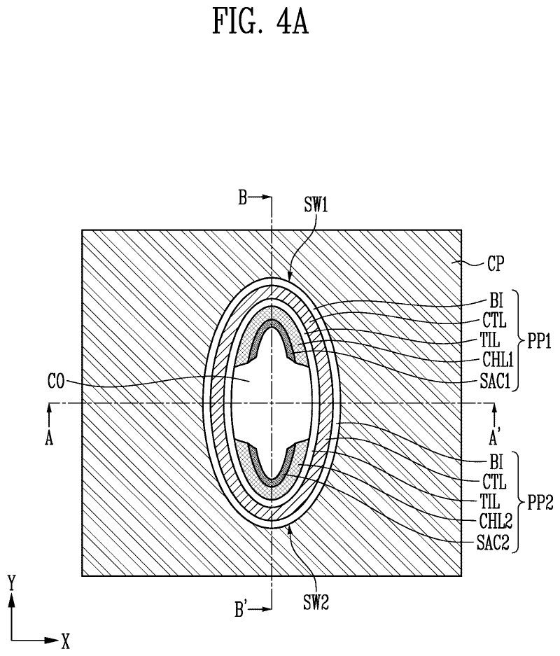

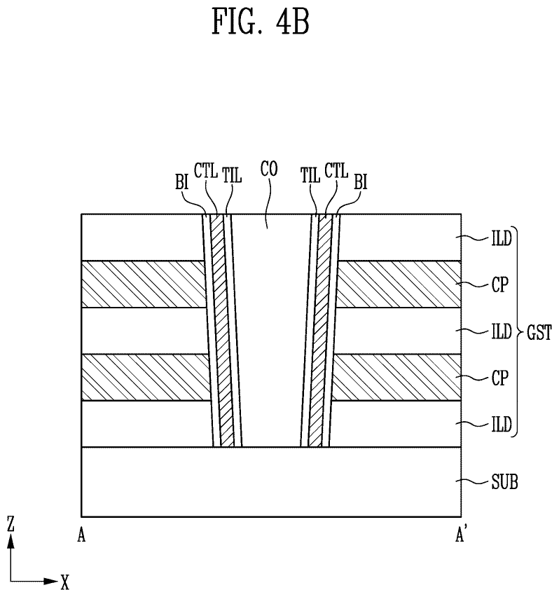

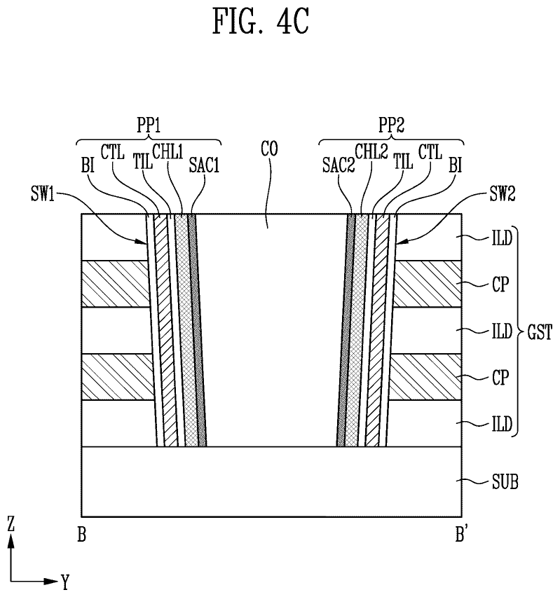

FIGS. 4A, 4B, and 4C are a plan view and sectional views for describing a semiconductor memory device according to an embodiment of the present disclosure.

FIGS. 4A, 4B, and 4C are a plan view and sectional views illustrating a portion of the memory cell array 110 of FIG. 1.

Referring to FIGS. 4A, 4B, and 4C, the semiconductor memory device may include a gate stacked structure GST and a first plug pattern PP1 and a second plug pattern PP2, which extend in a direction (Z) normal to a substrate SUB, in the gate stacked structure GST.

The gate stacked structure GST may include conductive layers CP and interlayer insulating layers ILD that are alternately stacked. The conductive layers CP may be gate electrodes of select transistors, memory cells, or the like. The conductive layers CP may be select lines connected to the select transistors and word lines connected to the memory cells. The conductive layers CP may contain a conductive material, such as polysilicon, tungsten, or metal. The interlayer insulating layers ILD may be used to insulate the stacked conductive layers CP from each other. The interlayer insulating layers ILD may contain an insulating material, such as an oxide or nitride.

The first plug pattern PP1 and the second plug pattern PP2 may extend in the direction (Z) normal to the substrate SUB by penetrating the gate stacked structure GST. That is, the first plug pattern PP1 and the second plug pattern PP2 may extend in the stacking direction of the gate stacked structure GST. The stacking direction of the gate stacked structure GST may be defined as the stacking direction of the conductive layers CP and the interlayer insulating layers ILD, which are alternately stacked and are included in the gate stacked structure GST. The first plug pattern PP1 and the second plug pattern PP2 may be arranged in one hole passing through the gate stacked structure GST.

The first plug pattern PP1 and the second plug pattern PP2 may have a symmetrical structure while being opposite each other in the second horizontal direction (Y) B-B′ of the hole that passes through the gate stacked structure GST to extend in the vertical direction (Z). For example, the first plug pattern PP1 and the second plug pattern PP2 may have mirror symmetry across the A-A′ section line. The second horizontal direction B-B′ may be a direction horizontal to the substrate SUB. A central portion of the hole may be filled with a core insulating layer CO, and the core insulating layer CO may extend in the vertical direction (Z) to physically and electrically separate a first channel layer CHL1 of the first plug pattern PP1 from a second channel layer CHL2 of the second plug pattern PP2. The core insulating layer CO may contain an insulating material, such as an oxide.

The first plug pattern PP1 may include a blocking insulating layer BI formed along a first sidewall SW1 of the hole, a charge trap layer CTL contacting the inner wall of the blocking insulating layer BI, a tunnel insulating layer TIL contacting the inner wall of the charge trap layer CTL, and the first channel layer CHL1 contacting the inner wall of the tunnel insulating layer TIL. The first plug pattern PP1 may further include a first sacrificial layer SAC1 contacting the inner wall of the first channel layer CHL1. The sidewall of the hole may refer to an inner sidewall of the gate stacked structure GST exposed by the hole passing through the gate stacked structure GST.

The first sacrificial layer SAC1 may contact the sidewall of the core insulating layer CO, the first channel layer CHL1 may contact the outer wall of the first sacrificial layer SAC1, the tunnel insulating layer TIL may contact the outer wall of the first channel layer CHL1, the charge trap layer CTL may contact the outer wall of the tunnel insulating layer TIL, and the blocking insulating layer BI may contact the outer wall of the charge trap layer CTL.

The second plug pattern PP2 may include a blocking insulating layer BI formed along a second sidewall SW2 of the hole opposite the first sidewall SW1, a charge trap layer CTL contacting the inner wall of the blocking insulating layer BI, a tunnel insulating layer TIL contacting the inner wall of the charge trap layer CTL, and the second channel layer CHL2 contacting the inner wall of the tunnel insulating layer TIL. The second plug pattern PP2 may further include a second sacrificial layer SAC2 contacting the inner wall of the second channel layer CHL2.

The second sacrificial layer SAC2 may contact the sidewall of the core insulating layer CO, the second channel layer CHL2 may contact the outer wall of the second sacrificial layer SAC2, the tunnel insulating layer TIL may contact the outer wall of the second channel layer CHL2, the charge trap layer CTL may contact the outer wall of the tunnel insulating layer TIL, and the blocking insulating layer BI may contact the outer wall of the charge trap layer CTL.

The first and second channel layers CHL1 and CHL2 may be regions in which channels such as select transistors or memory cells are formed. Each of the first and second channel layers CHL1 and CHL2 may include a semiconductor material, such as silicon or germanium, or may include a nanostructure, such as nanodots, nanotubes, or graphene. The tunnel insulating layer TIL may be a layer through which charges are tunneled by F-N tunneling or the like, and it may contain an insulating material, such as an oxide or nitride. The charge trap layer CTL may include a charge trap material, a nitride, a variable resistance material, a nanostructure, or a combination thereof. The blocking insulating layer BI may include a high dielectric layer.

The blocking insulating layer BI, the charge trap layer CTL, and the tunnel insulating layer TIL of the first plug pattern PP1 may be physically coupled to the blocking insulating layer BI, the charge trap layer CTL, and the tunnel insulating layer TIL of the second plug pattern PP2, respectively.

For example, the blocking insulating layer BI of the first plug pattern PP1 and the blocking insulating layer BI of the second plug pattern PP2 may be formed along the first sidewall SW1 and the second sidewall SW2 of the hole, respectively, and may be coupled to each other. Further, the charge trap layer CTL of the first plug pattern PP1 and the charge trap layer CTL of the second plug pattern PP2 may be formed along the inner walls of the corresponding blocking insulating layers BI, and they may be coupled to each other. Furthermore, the tunnel insulating layer TIL of the first plug pattern PP1 and the tunnel insulating layer TIL of the second plug pattern PP2 may be formed along the inner walls of the corresponding charge trap layers CTL, and they may be coupled to each other.

The first channel layer CHL1 of the first plug pattern PP1 and the second channel layer CHL2 of the second plug pattern PP2 may be separated from each other by the core insulating layer CO, and the first sacrificial layer SAC1 of the first plug pattern PP1 and the second sacrificial layer SAC2 of the second plug pattern PP2 may be separated from each other by the core insulating layer CO.

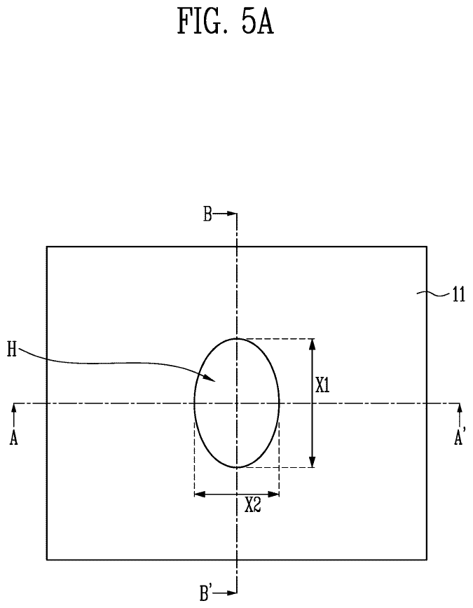

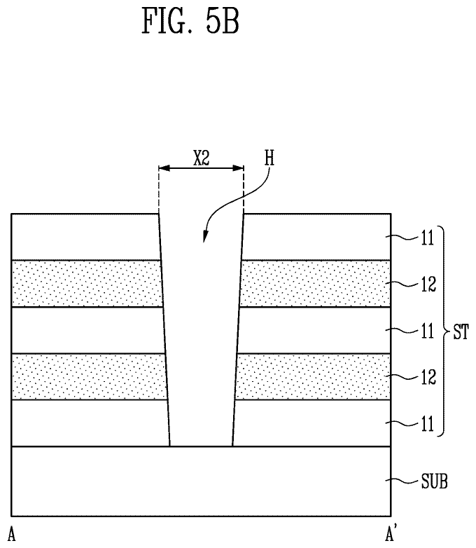

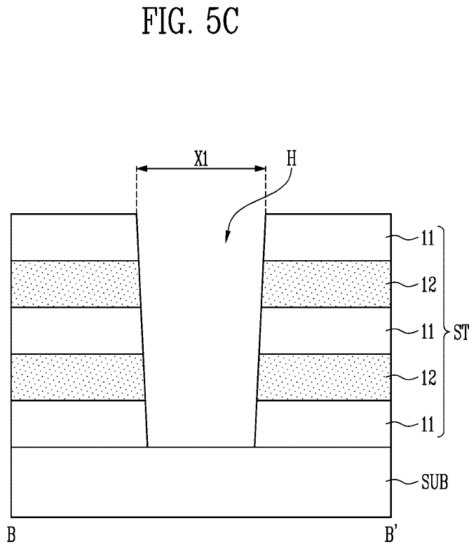

FIGS. 5A, 5B, 5C, 6A, 6B, 6C, 7, 8, 9, 10A, 10B, 10C, 11A, 11B, and 11C are plan views and sectional views for describing a method of manufacturing a semiconductor memory device according to an embodiment of the present disclosure.

Referring to FIGS. 5A, 5B, and 5C, a stacked structure ST is formed on a substrate SUB. The stacked structure ST may include first material layers 11 and second material layers 12 that are alternately stacked. The first and second material layers 11 and 12 may be stacked in a direction normal to the substrate SUB. The first and second material layers 11 and 12 may be formed using a deposition process, such as chemical vapor deposition (CVD).

The first material layers 11 may contain a material having a high etch selectivity with respect to the second material layers 12. In an example, the first material layers 11 may contain an insulating material, such as an oxide, and the second material layers 12 may contain a sacrificial material, such as a nitride. In an example, the first material layers 11 may contain an insulating material, such as an oxide, and the second material layers 12 may contain a conductive material, such as polysilicon or tungsten.

Also, a hard mask pattern (not illustrated) may be formed on the stacked structure ST, and a hole H passing through at least a portion of the stacked structure ST may be formed by performing an etching process that uses the hard mask pattern. The hole H may partially extend into the substrate SUB.

The hole H may be formed such that the width X2 of the hole H in a first horizontal direction A-A′ is smaller than the width X1 of the hole H in a second horizontal direction B-B′. For example, the cross-section of the hole H in the XY-plane may have an elliptical shape.

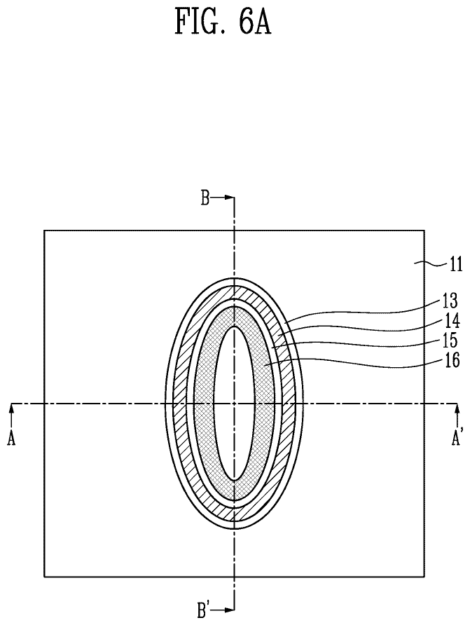

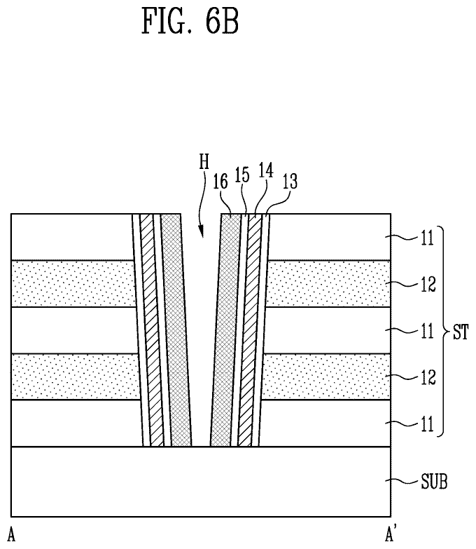

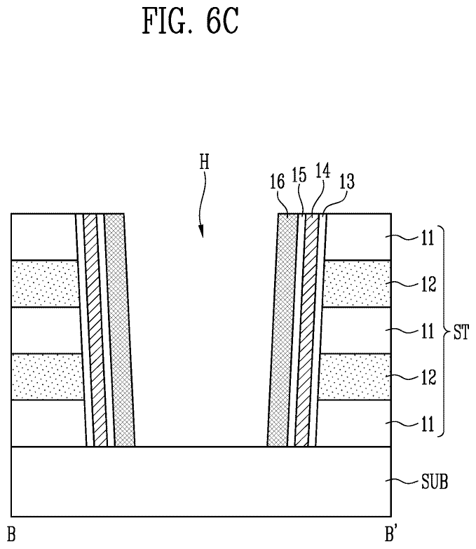

Referring to FIGS. 6A, 6B, and 6C, a blocking insulating layer 13, a charge trap layer 14, a tunnel insulating layer 15, and a preliminary channel layer 16 are sequentially formed along the sidewall of the hole H. For example, the blocking insulating layer 13 is formed along the sidewall of the hole H. The blocking insulating layer 13 may be a high dielectric layer. Thereafter, the charge trap layer 14 may be formed along the inner wall of the blocking insulating layer 13. The charge trap layer 14 may include a charge trap material, a nitride, a variable resistance material, a nanostructure, or a combination thereof. Thereafter, the tunnel insulating layer 15 may be formed along the inner wall of the charge trap layer 14. The tunnel insulating layer 15 may be a layer through which charges are tunneled by F-N tunneling or the like, and it may contain an insulating material, such as an oxide or nitride. Thereafter, the preliminary channel layer 16 may be formed along the inner wall of the tunnel insulating layer 15. The preliminary channel layer 16 may include a semiconductor material, such as silicon or germanium, may include an oxide semiconductor material, such as ZnO, In₂O₃, InZnO, ZnSnO, InGaZnO, or ZnGaSnO, a two-dimensional (2D) semiconductor material, such as MoS₂, MoSe₂, WS₂, WSe₂, or SnS₂, or a nanostructure, such as nanodots, nanotubes, or graphene. The preliminary channel layer 16 may be formed to not completely fill the central region of the hole.

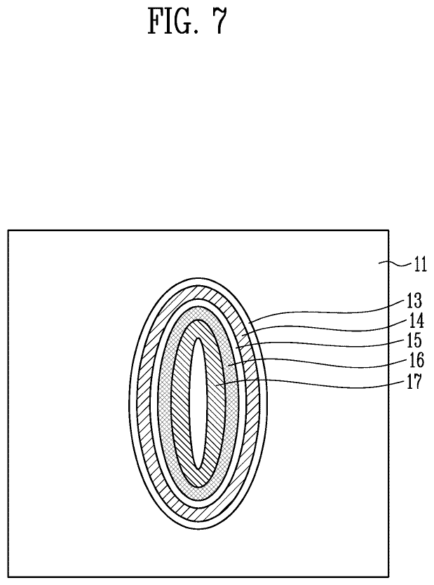

Referring to FIG. 7, a heat treatment (annealing) process on the preliminary channel layer 16 may be performed, and an oxide layer 17 may be formed by oxidizing an exposed inner wall of the preliminary channel layer 16. Accordingly, the thickness of the preliminary channel layer 16 may decrease.

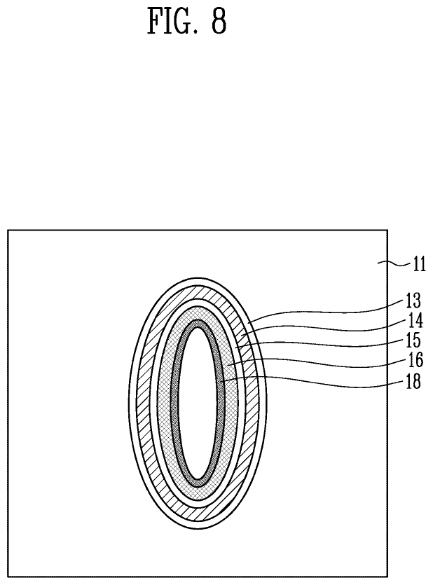

Referring to FIG. 8, the oxide layer (e.g., 17 of FIG. 7) may be removed by performing a strip process, and a sacrificial layer 18 may be formed by oxidizing the exposed inner wall of the preliminary channel layer 16. When the sacrificial layer 18 is formed through a deposition process, a portion of the sacrificial layer 18 corresponding to the uppermost portion of the hole may be formed to be relatively thick, and a portion of the sacrificial layer 18 corresponding to the bottom surface of the hole may be formed to be relatively thin, thus causing the thickness of the sacrificial layer 18 to be non-uniformly distributed. When the sacrificial layer 18 is formed through an oxidation process, the thicknesses of the sacrificial layer 18 corresponding to the uppermost portion and the bottom surface of the hole may be uniformly formed. Further, the sacrificial layer formed through the oxidation process may have fewer dangling bonds at an interface with the preliminary channel layer 16 than the sacrificial layer formed through the deposition process, thus exhibiting improved performance in terms of current flow and leakage current, for some embodiments. Furthermore, the sacrificial layer 18 formed through the oxidation process may have a higher etch selectivity with respect to the preliminary channel layer 16 than that of the sacrificial layer formed through the deposition process.

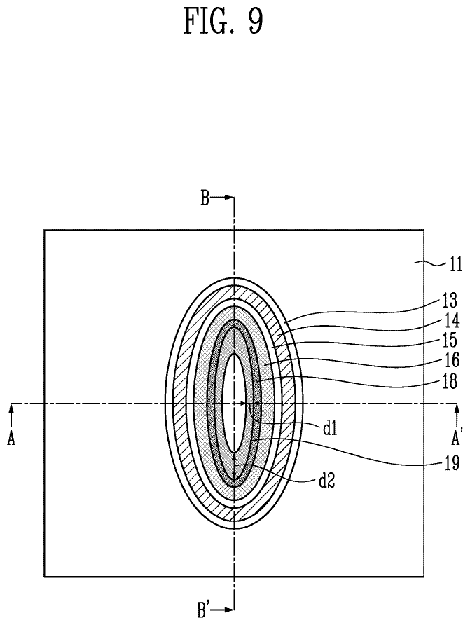

Referring to FIG. 9, a barrier layer 19 is formed along the inner wall of the sacrificial layer 18. The barrier layer 19 may include a polysilicon layer. The thickness d1 of the barrier layer 19 formed on the sidewall of the hole H in the first horizontal direction A-A′ and the thickness d2 of the barrier layer 19 formed on the sidewall of the hole H in the second horizontal direction B-B′ may be formed to be different from each other. For example, the thickness d1 of the barrier layer 19 formed on the sidewall of the hole H in the first horizontal direction A-A′ may be smaller than the thickness d2 of the barrier layer 19 formed on the sidewall of the hole H in the second horizontal direction B-B′.

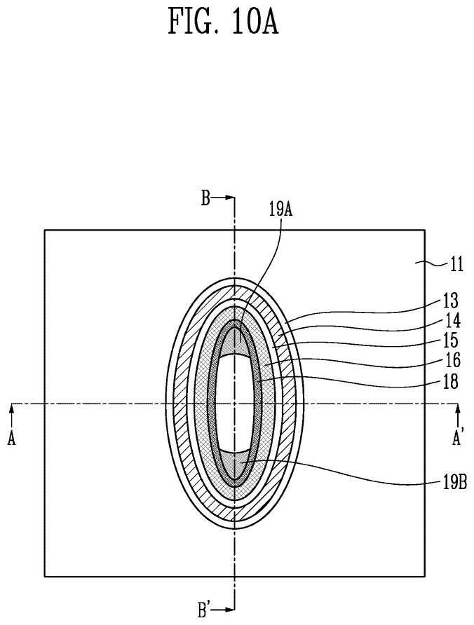

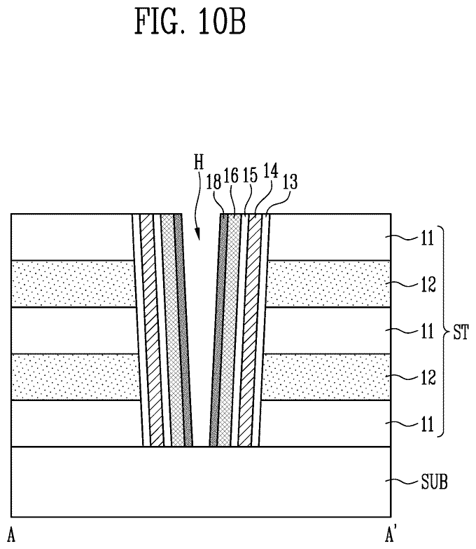

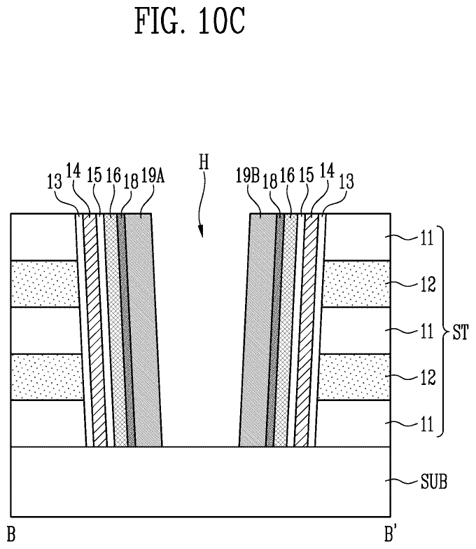

Referring to FIGS. 10A, 10B, and 10C, the barrier layer (e.g., 19 of FIG. 9) may be etched to a certain thickness by performing an etching process, and it may then be partially removed. The etching process may be performed using an isotropic etching process. For example, a portion of the barrier layer (e.g., 19 of FIG. 9) may be etched and removed such that the sidewall of the sacrificial layer 18 in the first horizontal direction A-A′ is exposed. During the etching process, the thickness of the barrier layer (e.g., 19 of FIG. 9) formed on the sidewall of the sacrificial layer 18 in the first horizontal direction A-A′ is smaller than the thickness of the barrier layer (e.g., 19 of FIG. 9) formed on the sidewall of the sacrificial layer 18 in the second horizontal direction B-B′, and thus the barrier layer (e.g., 19 of FIG. 9) may remain on the sidewall of the sacrificial layer 18 in the second horizontal direction B-B′ even if the barrier layer (e.g., 19 of FIG. 9) is etched to expose the sidewall of the sacrificial layer 18 in the first horizontal direction A-A′. The remaining barrier layer may be defined as the barrier patterns 19A and 19B. Also, during the isotropic etching process, due to differences in a surface area and a surface angle exposed to the etchant, an etching rate in the first horizontal direction A-A′ may be higher than an etching rate in the second horizontal direction B-B′. Due thereto, the barrier patterns 19A and 19B may be formed on opposite sidewalls of the hole H in the second horizontal direction B-B′. The horizontal cross-section of each of the barrier patterns 19A and 19B may have a crescent shape.

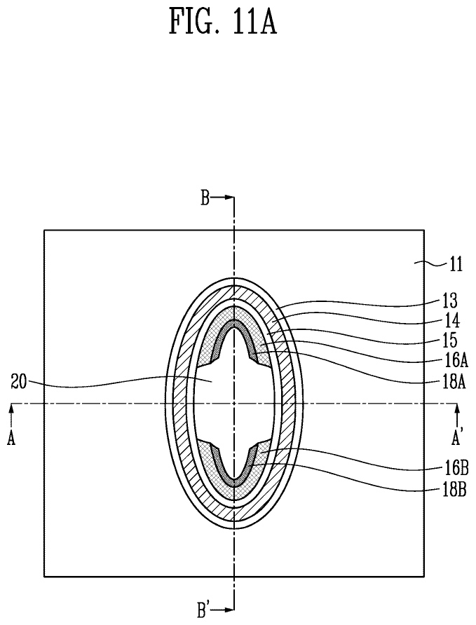

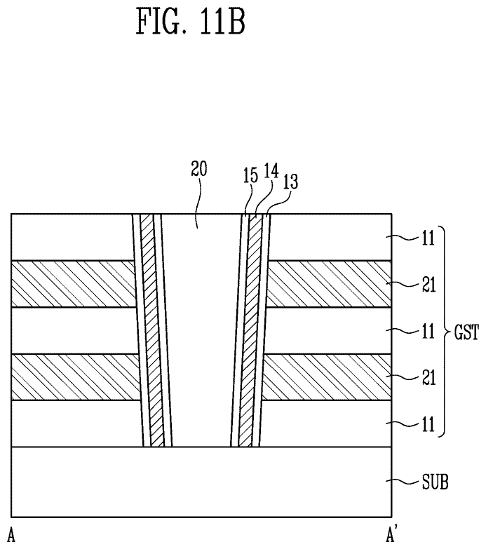

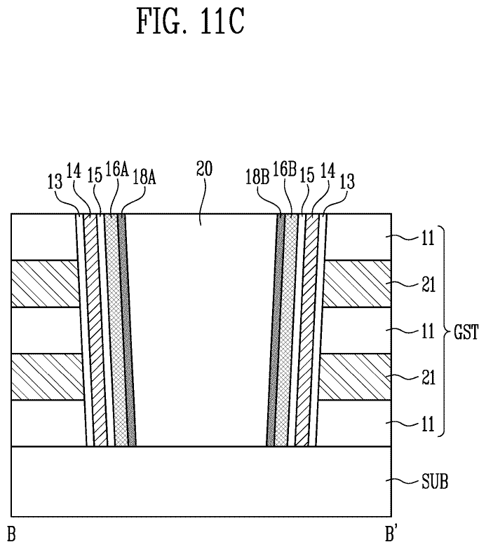

Referring to FIGS. 11A, 11B, and 11C, the sacrificial layer exposed by performing an etching process that uses the barrier patterns (e.g., 19A and 19B of FIGS. 10A, 10B and 10C) as a mask may be partially etched, thus exposing the preliminary channel layer (e.g., 16 of FIGS. 10A, 10B, and 10C) in the first horizontal direction A-A′. Accordingly, the sacrificial layer may be patterned into a first sacrificial layer 18A and a second sacrificial layer 18B that are separated from each other. Thereafter, the preliminary channel layer (e.g., 16 of FIGS. 10A, 10B, and 10C) exposed by performing an etching process that uses the first sacrificial layer 18A and the second sacrificial layer 18B as a mask may be etched, thus exposing the tunnel insulating layer 15 in the first horizontal direction A-A′. Accordingly, the preliminary channel layer may be patterned into a first channel layer 16A and a second channel layer 16B that are separated from each other. Thereafter, the barrier patterns may be removed.

Thereafter, a core insulating layer 20 may be formed to fill the central region of the hole (e.g., H of FIGS. 10B and 10C). The core insulating layer 20 may contain an insulating material, such as an oxide.

Thereafter, an etching process may be performed to expose the sidewall of the stacked structure (e.g., ST of FIGS. 10B and 10C), and the exposed second material layers (e.g., 12 of FIGS. 10B and 10C) may be removed. Thereafter, in spaces from which the second material layers are removed, third material layers 21 may be formed. The third material layers 21 may contain a conductive material, such as polysilicon, tungsten, or metal. Due thereto, a gate stacked structure GST including the first material layers 11 and the third material layers 21 may be formed.

As described above, according to an embodiment of the present disclosure, the preliminary channel layer 16 and the sacrificial layer 18 may be formed through a deposition-anneal-oxidation (DAO) scheme including a deposition process, an annealing process, and an oxidation process, and thus the layer quality of the preliminary channel layer 16 and the sacrificial layer 18 may be improved, with the result that the channel current of the memory cell string may be increased and leakage current may be reduced.

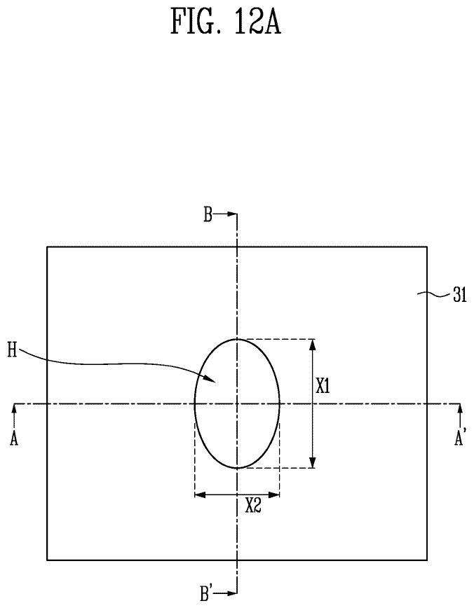

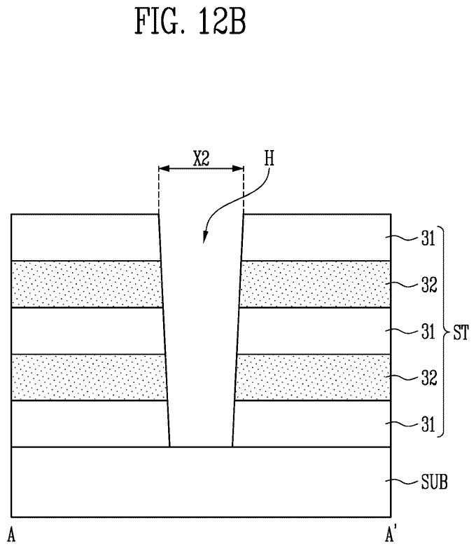

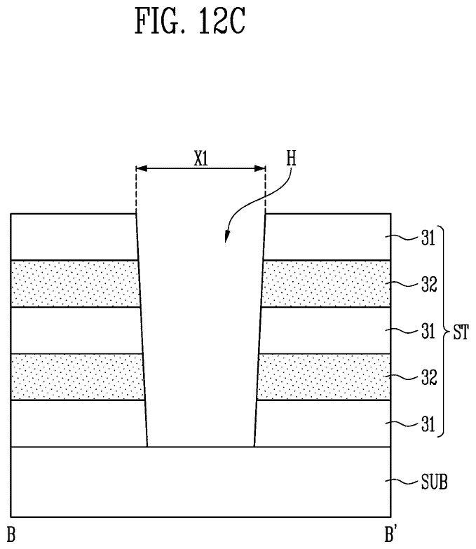

FIGS. 12A, 12B, 12C, 13A, 13B, 13C, 14, 15, 16, 17A, 17B, 17C, 18A, 18B, and 18C are plan views and sectional views for describing a method of manufacturing a semiconductor memory device according to an embodiment of the present disclosure.

Referring to FIGS. 12A, 12B, and 12C, a stacked structure ST is formed on a substrate SUB. The stacked structure ST may include first material layers 31 and second material layers 32 that are alternately stacked. The first and second material layers 31 and 32 may be stacked in a direction normal to the substrate SUB. The first and second material layers 31 and 32 may be formed using a deposition process, such as chemical vapor deposition (CVD).

The first material layers 31 may contain a material having a high etch selectivity with respect to the second material layers 32. In an example, the first material layers 31 may contain an insulating material, such as an oxide, and the second material layers 32 may contain a sacrificial material, such as a nitride. In an example, the first material layers 31 may contain an insulating material, such as an oxide, and the second material layers 32 may contain a conductive material, such as polysilicon or tungsten.

Also, a hard mask pattern (not illustrated) may be formed on the stacked structure ST, and a hole H passing through at least a portion of the stacked structure ST may be formed by performing an etching process that uses the hard mask pattern. The hole H may partially extend into the substrate SUB.

The hole H may be formed such that the width X2 of the hole H in a first horizontal direction A-A′ is smaller than the width X1 of the hole H in a second horizontal direction B-B′. For example, the cross-section of the hole H in the XY-plane may have an elliptical shape.

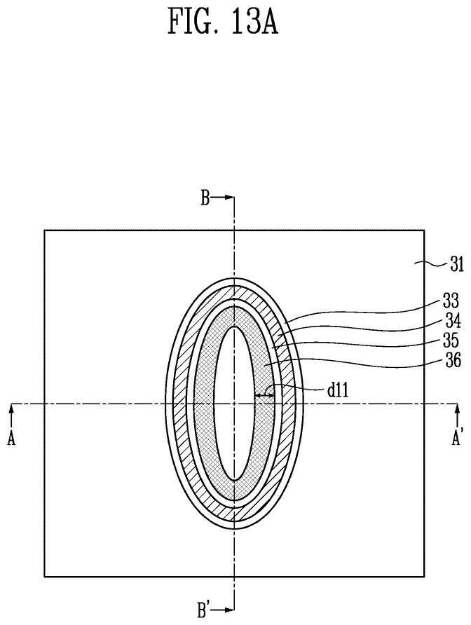

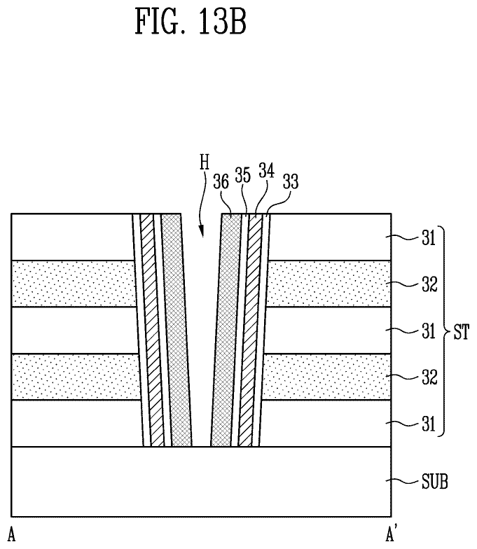

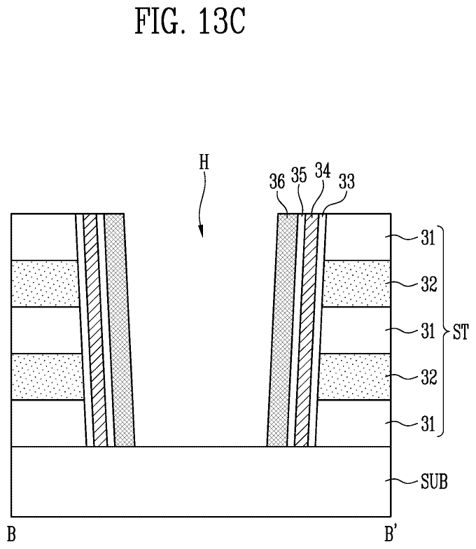

Referring to FIGS. 13A, 13B, and 13C, a blocking insulating layer 33, a charge trap layer 34, a tunnel insulating layer 35, and a preliminary channel layer 36 are sequentially formed along the sidewall of the hole H. For example, the blocking insulating layer 33 is formed along the sidewall of the hole H. The blocking insulating layer 33 may be a high dielectric layer. Thereafter, the charge trap layer 34 may be formed along the inner wall of the blocking insulating layer 33. The charge trap layer 34 may include a charge trap material, a nitride, a variable resistance material, a nanostructure, or a combination thereof. Thereafter, the tunnel insulating layer 35 may be formed along the inner wall of the charge trap layer 34. The tunnel insulating layer 35 may be a layer through which charges are tunneled by F-N tunneling or the like, and it may contain an insulating material, such as an oxide or nitride. Thereafter, the preliminary channel layer 36 may be formed along the inner wall of the tunnel insulating layer 35. The preliminary channel layer 36 may include a semiconductor material, such as silicon or germanium, may include an oxide semiconductor material, such as ZnO, In₂O₃, InZnO, ZnSnO, InGaZnO, or ZnGaSnO, a two-dimensional (2D) semiconductor material, such as MoS₂, MoSe₂, WS₂, WSe₂, or SnS₂, or a nanostructure, such as nanodots, nanotubes, or graphene. The preliminary channel layer 36 may be formed to not completely fill the central region of the hole. The preliminary channel layer 36 may be formed to have a first thickness d11. Thereafter, an annealing process may be performed on the preliminary channel layer 36.

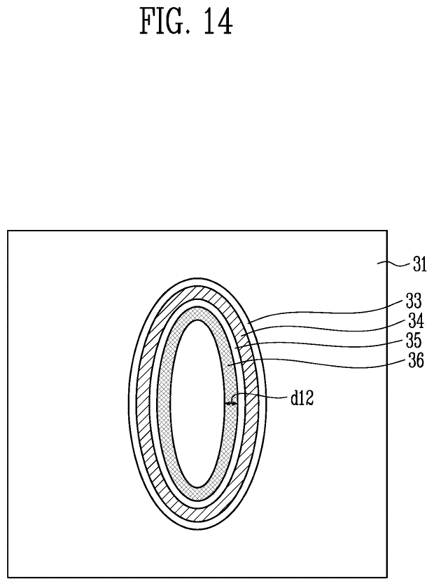

Referring to FIG. 14, an etching process may be performed such that the thickness of the preliminary channel layer 36 decreases. Accordingly, the preliminary channel layer 36 may be etched down to a second thickness d12.

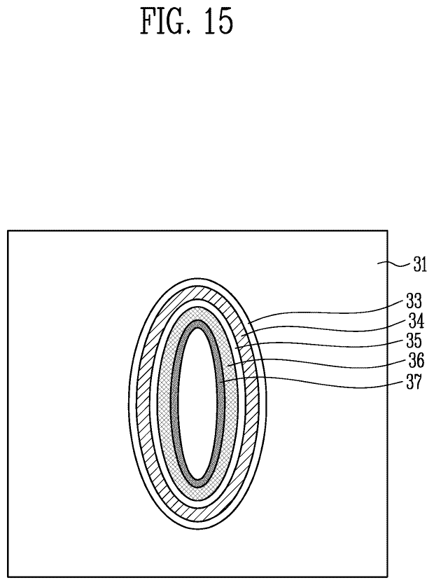

Referring to FIG. 15, a sacrificial layer 37 is formed by oxidizing the exposed inner wall of the preliminary channel layer 36. When the sacrificial layer 37 is formed through a deposition process, a portion of the sacrificial layer 37 corresponding to the uppermost portion of the hole may be formed to be relatively thick, and a portion of the sacrificial layer 37 corresponding to the bottom surface of the hole may be formed to be relatively thin, thus causing the thickness of the sacrificial layer 18 to be non-uniformly distributed. When the sacrificial layer 37 is formed through an oxidation process, the thicknesses of the sacrificial layer 37 corresponding to the uppermost portion and the bottom surface of the hole may be uniformly formed. Further, the sacrificial layer formed through the oxidation process may have fewer dangling bonds at an interface with the preliminary channel layer 36 than the sacrificial layer formed through the deposition process, thus exhibiting improved performance in terms of current flow and leakage current, for some embodiments. Furthermore, the sacrificial layer 37 formed through the oxidation process may have a higher etch selectivity with respect to the preliminary channel layer 36 than that of the sacrificial layer formed through the deposition process.

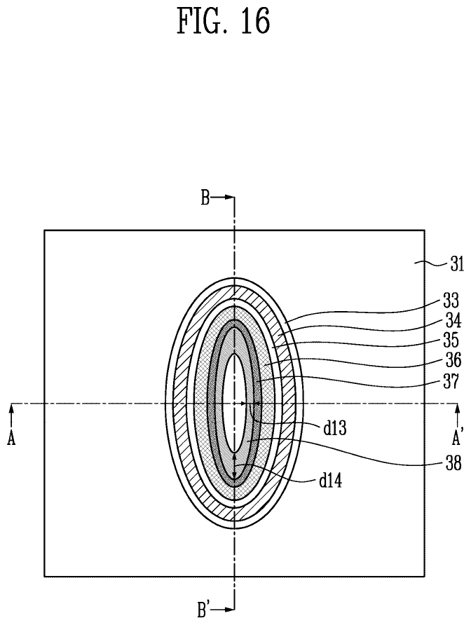

Referring to FIG. 16, a barrier layer 38 is formed along the inner wall of the sacrificial layer 37. The barrier layer 38 may include a polysilicon layer. The thickness d13 of the barrier layer 38 formed on the sidewall of the hole H in the first horizontal direction A-A′ and the thickness d14 of the barrier layer 38 formed on the sidewall of the hole H in the second horizontal direction B-B′ may be formed to be different from each other. For example, the thickness d13 of the barrier layer 38 formed on the sidewall of the hole H in the first horizontal direction A-A′ may be smaller than the thickness d14 of the barrier layer 38 formed on the sidewall of the hole H in the second horizontal direction B-B′.

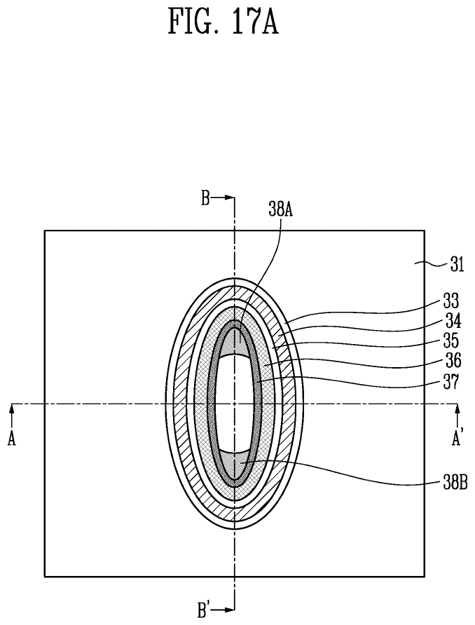

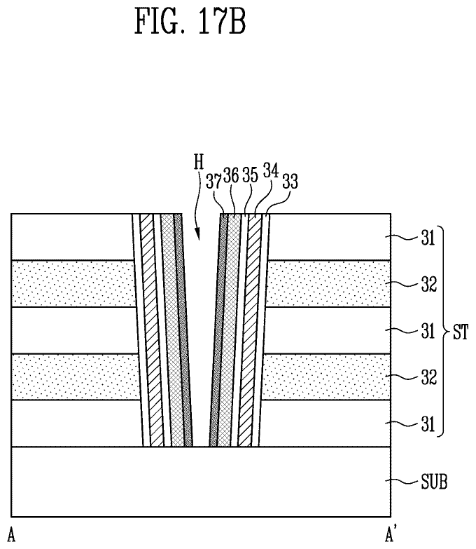

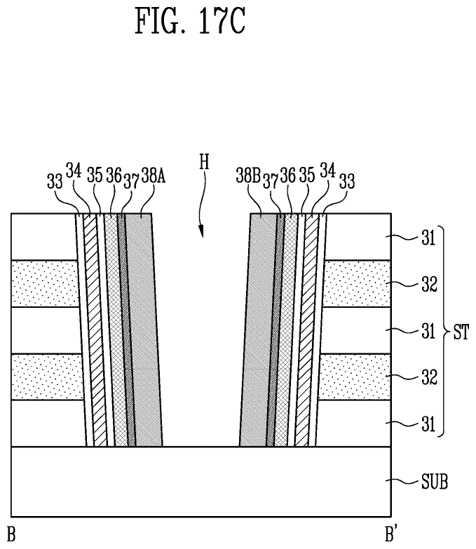

Referring to FIGS. 17A, 17B, and 17C, the barrier layer (e.g., 38 of FIG. 16) may be etched to a certain thickness by performing an etching process, and it may then be partially removed. The etching process may be performed using an isotropic etching process. For example, a portion of the barrier layer (e.g., 38 of FIG. 16) may be etched and removed such that the sidewall of the sacrificial layer 37 in the first horizontal direction A-A′ is exposed. During the etching process, the thickness of the barrier layer (e.g., 38 of FIG. 16) formed on the sidewall of the sacrificial layer 37 in the first horizontal direction A-A′ is smaller than the thickness of the barrier layer (e.g., 38 of FIG. 16) formed on the sidewall of the sacrificial layer 37 in the second horizontal direction B-B′, and thus the barrier layer (e.g., 38 of FIG. 16) may remain on the sidewall of the sacrificial layer 37 in the second horizontal direction B-B′ even if the barrier layer (e.g., 38 of FIG. 16) is etched to expose the sidewall of the sacrificial layer 37 in the first horizontal direction A-A′. The remaining barrier layer may be defined as the barrier patterns 38A and 38B. Also, during the isotropic etching process, due to differences in a surface area and a surface angle exposed to the etchant, an etching rate in the first horizontal direction A-A′ may be higher than an etching rate in the second horizontal direction B-B′. Due thereto, the barrier patterns 38A and 38B may be formed on opposite sidewalls of the hole H in the second horizontal direction B-B′. The horizontal cross-section of each of the barrier patterns 38A and 38B may have a crescent shape.

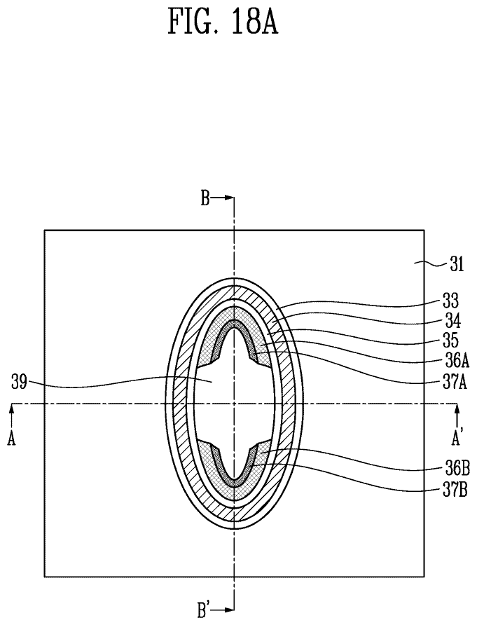

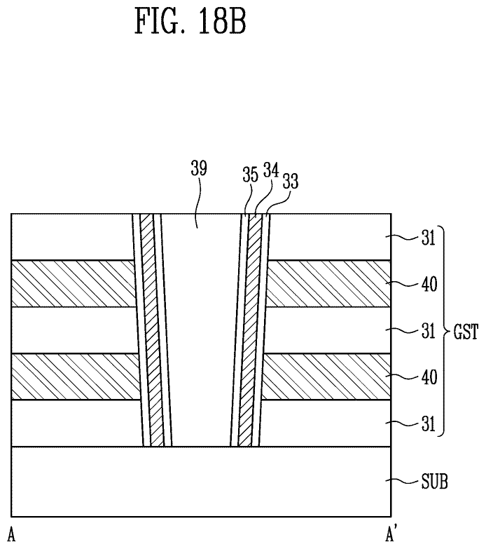

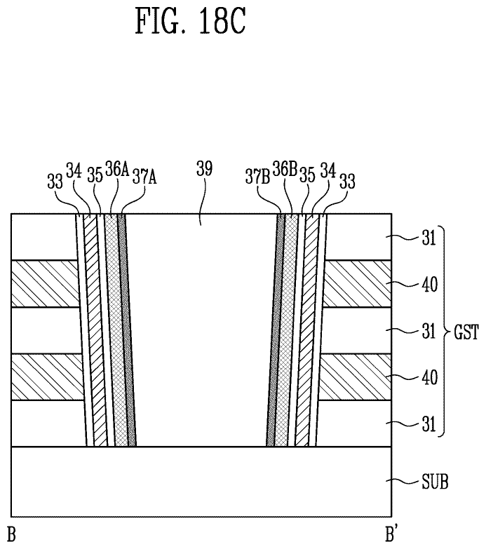

Referring to FIGS. 18A, 18B, and 18C, the sacrificial layer exposed by performing an etching process that uses the barrier patterns (e.g., 38A and 38B of FIGS. 17A, 17B and 17C) as a mask may be partially etched, thus exposing the preliminary channel layer (e.g., 36 of FIGS. 17A, 17B, and 17C) in the first horizontal direction A-A′. Accordingly, the sacrificial layer may be patterned into a first sacrificial layer 37A and a second sacrificial layer 37B that are separated from each other. Thereafter, the preliminary channel layer (e.g., 36 of FIGS. 17A, 17B, and 17C) exposed by performing an etching process that uses the first sacrificial layer 37A and the second sacrificial layer 37B as a mask may be etched, thus exposing the tunnel insulating layer 35 in the first horizontal direction A-A′. Accordingly, the preliminary channel layer may be patterned into a first channel layer 36A and a second channel layer 36B that are separated from each other. Thereafter, the barrier patterns may be removed.

Thereafter, a core insulating layer 39 may be formed to fill the central region of the hole (e.g., H of FIGS. 17A, 17B, and 17C). The core insulating layer 39 may contain an insulating material, such as an oxide.

Thereafter, an etching process may be performed to expose the sidewall of the stacked structure (e.g., ST of FIGS. 17A, 17B, and 17C), and the exposed second material layers (e.g., 32 of FIGS. 17A, 17B, and 17C) may be removed. Thereafter, in spaces from which the second material layers are removed, third material layers 40 may be formed. The third material layers 40 may contain a conductive material, such as polysilicon, tungsten, or metal. Due thereto, a gate stacked structure GST including the first material layers 31 and the third material layers 40 may be formed.

As described above, according to an embodiment of the present disclosure, the preliminary channel layer 36 and the sacrificial layer 37 may be formed through a DAO scheme including a deposition process, an annealing process, and an oxidation process, and thus the layer quality of the preliminary channel layer 36 and the sacrificial layer 37 may be improved, with the result that the channel current of the memory cell string may be increased, and leakage current may be reduced.

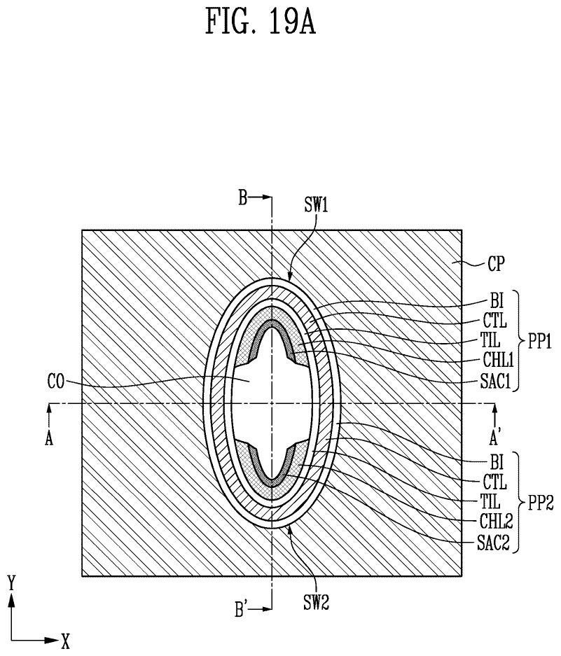

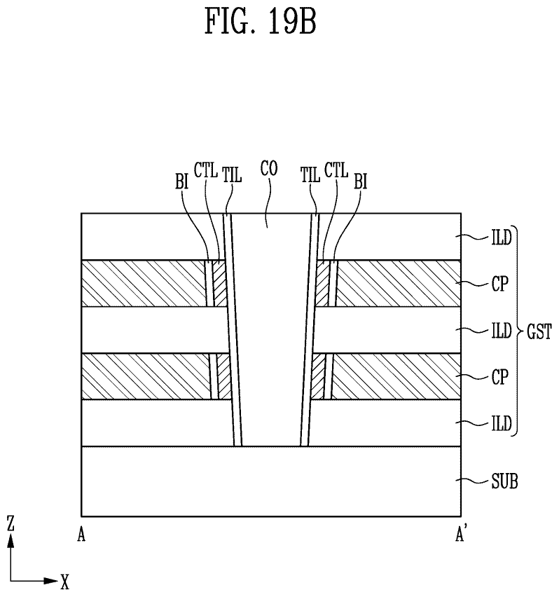

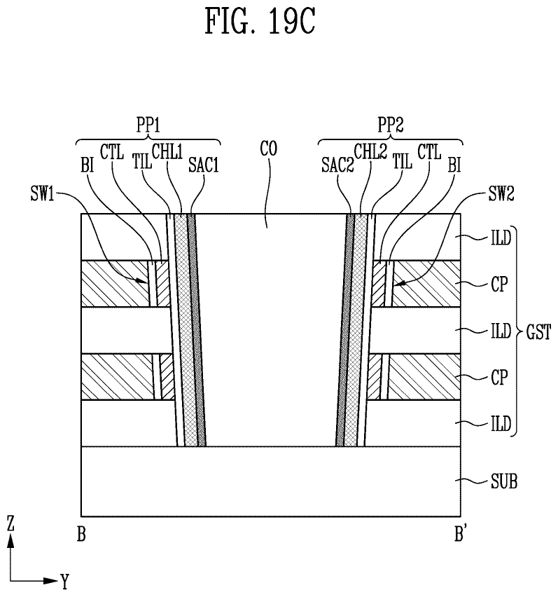

FIGS. 19A, 19B, and 19C are a plan view and sectional views for describing a semiconductor memory device according to an embodiment of the present disclosure.

FIGS. 19A, 19B, and 19C are a plan view and sectional views illustrating a portion of the memory cell array 110 of FIG. 1.

Referring to FIGS. 19A, 19B, and 19C, the semiconductor memory device may include a gate stacked structure GST and also a first plug pattern PP1 and a second plug pattern PP2, which extend in a direction (Z) normal to a substrate SUB, in the gate stacked structure GST.

The gate stacked structure GST may include conductive layers CP and interlayer insulating layers ILD that are alternately stacked. The conductive layers CP may be gate electrodes of select transistors, memory cells, or the like. The conductive layers CP may be select lines connected to the select transistors and word lines connected to the memory cells. The conductive layers CP may contain a conductive material, such as polysilicon, tungsten, or metal. The interlayer insulating layers ILD may be used to insulate the stacked conductive layers CP from each other. The interlayer insulating layers ILD may contain an insulating material, such as an oxide or nitride.

The interlayer insulating layers ILD may extend farther than the conductive layers CP in the direction of the first plug pattern PP1 and the second plug pattern PP2.

The first plug pattern PP1 and the second plug pattern PP2 may extend in the direction (Z) normal to the substrate SUB by penetrating the gate stacked structure GST. That is, the first plug pattern PP1 and the second plug pattern PP2 may extend in the stacking direction of the gate stacked structure GST. The stacking direction of the gate stacked structure GST may be defined as the stacking direction of the conductive layers CP and the interlayer insulating layers ILD, which are alternately stacked and are included in the gate stacked structure GST. The first plug pattern PP1 and the second plug pattern PP2 may both be arranged in one hole passing through the gate stacked structure GST.

The first plug pattern PP1 and the second plug pattern PP2 may have a symmetrical structure while being opposite each other in the second horizontal direction (Y) B-B′ of the hole that passes through the gate stacked structure GST to extend in the vertical direction (Z). For example, the first plug pattern PP1 and the second plug pattern PP2 may have mirror symmetry across the A-A′ section line. The second horizontal direction B-B′ may be a direction horizontal to the substrate SUB. A central portion of the hole may be filled with a core insulating layer CO, and the core insulating layer CO may extend in the vertical direction (Z) to physically and electrically separate a first channel layer CHL1 of the first plug pattern PP1 from a second channel layer CHL2 of the second plug pattern PP2. The core insulating layer CO may contain an insulating material, such as an oxide.

The first plug pattern PP1 may include a blocking insulating layer BI, a charge trap layer CTL, a tunnel insulating layer TIL, and the first channel layer CHL1, which are sequentially arranged between the conductive layers CP and the core insulating layer CO. The first plug pattern PP1 may further include a first sacrificial layer SAC1. For example, the blocking insulating layer BI may be formed along the first sidewalls SW1 of the conductive layers CP, and the charge trap layer CTL may be formed along the inner wall of the blocking insulating layer BI. The blocking insulating layer BI and the charge trap layer CTL corresponding to one memory cell may be physically separated from the blocking insulating layer BI and the charge trap layer CTL of a memory cell adjacent to the one memory cell in a vertical direction (Z) by the interlayer insulating layers ILD. The tunnel insulating layer TIL may be formed along the inner wall of the charge trap layer CTL, and may extend in a vertical direction along the sidewalls of the interlayer insulating layers ILD. The first channel layer CHL1 may extend in the vertical direction (Z) along the inner wall of the tunnel insulating layer TIL. The first sacrificial layer SAC1 may extend in the vertical direction along the inner wall of the first channel layer CHL1.

The second plug pattern PP2 may include a blocking insulating layer BI, a charge trap layer CTL, a tunnel insulating layer TIL, and the second channel layer CHL2, which are sequentially arranged between the conductive layers CP and the core insulating layer CO. The second plug pattern PP2 may further include a second sacrificial layer SAC2. For example, the blocking insulating layer BI may be formed along the second sidewalls SW2 of the conductive layers CP, and the charge trap layer CTL may be formed along the inner wall of the blocking insulating layer BI. The blocking insulating layer BI and the charge trap layer CTL corresponding to one memory cell may be physically separated from the blocking insulating layer BI and the charge trap layer CTL of a memory cell adjacent to the one memory cell in a vertical direction (Z) by the interlayer insulating layers ILD. The tunnel insulating layer TIL may be formed along the inner wall of the charge trap layer CTL, and may extend in a vertical direction along the sidewalls of the interlayer insulating layers ILD. The second channel layer CHL2 may extend in the vertical direction (Z) along the inner wall of the tunnel insulating layer TIL. The second sacrificial layer SAC2 may extend in the vertical direction along the inner wall of the second channel layer CHL2.

The first and second channel layers CHL1 and CHL2 may be regions in which channels such as select transistors or memory cells are formed. Each of the first and second channel layers CHL1 and CHL2 may include a semiconductor material, such as silicon or germanium, or may include a nanostructure, such as nanodots, nanotubes, or graphene. The tunnel insulating layer TIL may be a layer through which charges are tunneled by F-N tunneling or the like, and it may contain an insulating material, such as an oxide or nitride. The charge trap layer CTL may include a charge trap material, a nitride, a variable resistance material, a nanostructure, or a combination thereof. The blocking insulating layer BI may include a high dielectric layer.

The blocking insulating layer BI, the charge trap layer CTL, and the tunnel insulating layer TIL of the first plug pattern PP1 may be physically coupled to the blocking insulating layer BI, the charge trap layer CTL, and the tunnel insulating layer TIL of the second plug pattern PP2, respectively.

For example, the blocking insulating layer BI of the first plug pattern PP1 and the blocking insulating layer BI of the second plug pattern PP2 may be formed along the first sidewall SW1 and the second sidewall SW2 of the conductive layers CP, respectively, and they may be coupled to each other. Further, the charge trap layer CTL of the first plug pattern PP1 and the charge trap layer CTL of the second plug pattern PP2 may be formed along the inner walls of the corresponding blocking insulating layers BI, and may be coupled to each other. Furthermore, the tunnel insulating layer TIL of the first plug pattern PP1 and the tunnel insulating layer TIL of the second plug pattern PP2 may be formed along the inner walls of the corresponding charge trap layers CTL, and they may be coupled to each other.

The first channel layer CHL1 of the first plug pattern PP1 and the second channel layer CHL2 of the second plug pattern PP2 may be separated from each other by the core insulating layer CO, and the first sacrificial layer SAC1 of the first plug pattern PP1 and the second sacrificial layer SAC2 of the second plug pattern PP2 may be separated from each other by the core insulating layer CO.

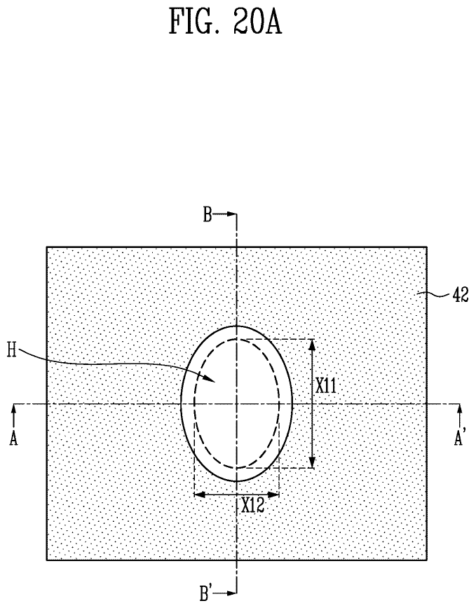

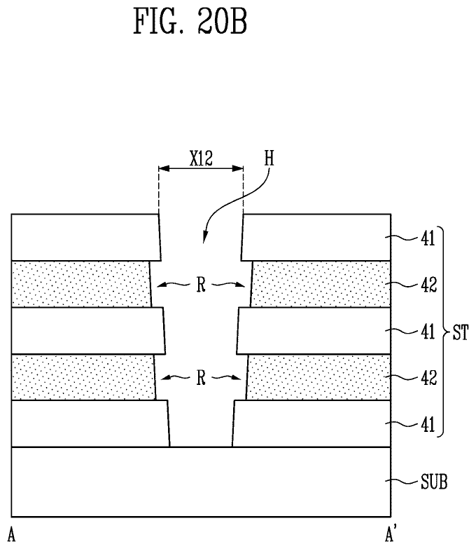

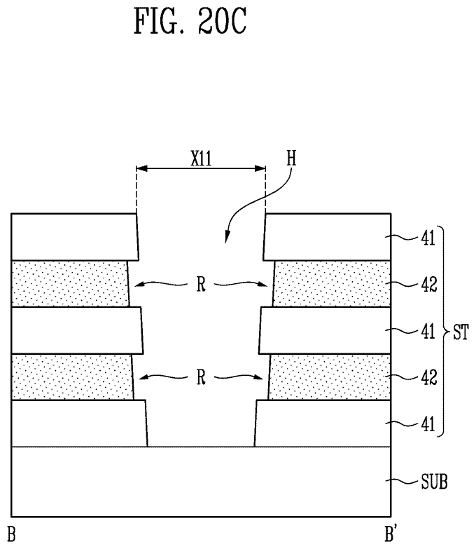

FIGS. 20A, 20B, 20C, 21A, 21B, 21C, 22, 23, 24, 25A, 25B, 25C, 26A, 26B, and 26C are plan views and sectional views for describing a method of manufacturing a semiconductor memory device according to an embodiment of the present disclosure.

Referring to FIGS. 20A, 20B, and 20C, a stacked structure ST is formed on a substrate SUB. The stacked structure ST may include first material layers 41 and second material layers 42 that are alternately stacked. The first and second material layers 41 and 42 may be stacked in a direction normal to the substrate SUB. The first and second material layers 41 and 42 may be formed using a deposition process, such as chemical vapor deposition (CVD).

The first material layers 41 may contain a material having a high etch selectivity with respect to the second material layers 42. In an example, the first material layers 41 may contain an insulating material, such as an oxide, and the second material layers 42 may contain a sacrificial material, such as a nitride. In an example, the first material layers 41 may contain an insulating material, such as an oxide, and the second material layers 42 may contain a conductive material, such as polysilicon or tungsten.

Also, a hard mask pattern (not illustrated) may be formed on the stacked structure ST, and a hole H passing through at least a portion of the stacked structure ST may be formed by performing an etching process that uses the hard mask pattern. The hole H may partially extend into the substrate SUB.

The hole H may be formed such that the width X12 of the hole H in a first horizontal direction A-A′ is smaller than the width X11 of the hole H in a second horizontal direction B-B′. For example, the cross-section of the hole H in the XY-plane may have an elliptical shape.

Thereafter, recess regions R may be formed by etching the sidewalls of the second material layers 42 exposed through the hole H to a recessed depth. For example, the sidewalls of the second material layers 42 may be etched to the recessed depth so that the first material layers 42 protrude beyond the second material layers 42 in the direction of the hole H. Due thereto, the sidewall of the hole H may be formed in a structure in which irregular portions (concave/convex portions) are sequentially arranged in the direction normal to the substrate SUB.

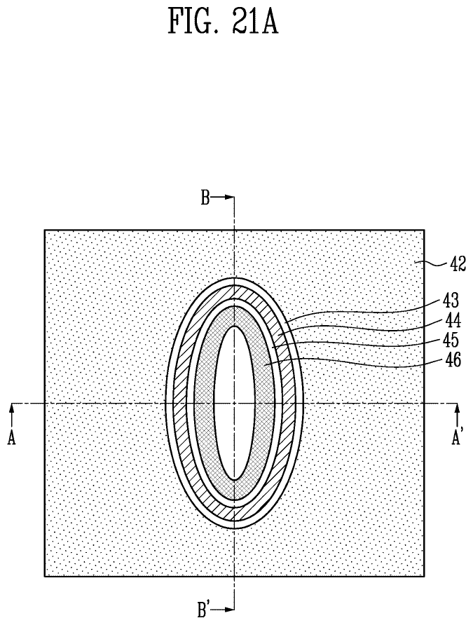

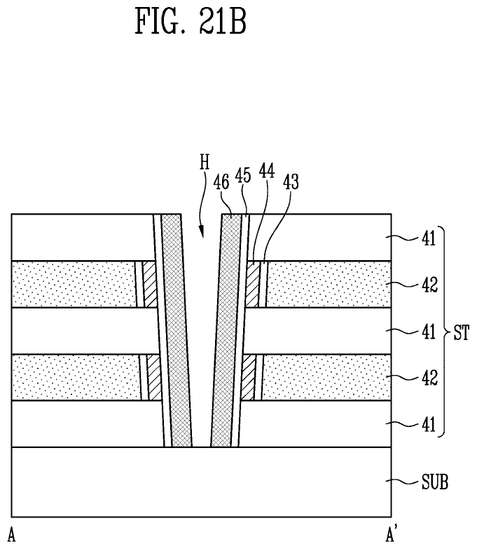

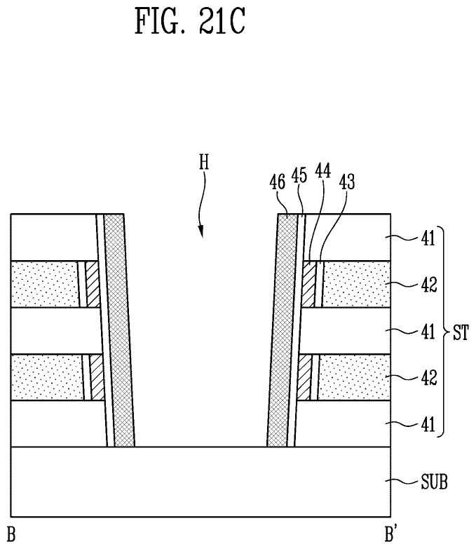

Referring to FIGS. 21A, 21B, and 21C, a blocking insulating layer 43 and a charge trap layer 44 are formed in each recess region (e.g., R of FIGS. 20B and 20C) of the hole H.

For example, the blocking insulating layer 43 and the charge trap layer 44 are sequentially formed along the sidewall of the hole H. Also, the blocking insulating layer 43 and the charge trap layer 44 may remain only in the recess regions (e.g., R of FIGS. 20B and 20C) by performing an etching process so that the sidewalls of the first material layers 41 are exposed.

Thereafter, a tunnel insulating layer 45 and a preliminary channel layer 46 are sequentially formed along the inner walls of the charge trap layer 44 and the sidewalls of the first material layers 41. The charge trap layer 44 may include a charge trap material, a nitride, a variable resistance material, a nanostructure, or a combination thereof. Thereafter, the tunnel insulating layer 45 may be formed along the inner wall of the charge trap layer 44. The tunnel insulating layer 45 may be a layer through which charges are tunneled by F-N tunneling or the like, and it may contain an insulating material, such as an oxide or nitride. Thereafter, the preliminary channel layer 46 may be formed along the inner wall of the tunnel insulating layer 45. The preliminary channel layer 46 may include a semiconductor material, such as silicon or germanium, may include an oxide semiconductor material, such as ZnO, In₂O₃, InZnO, ZnSnO, InGaZnO, or ZnGaSnO, a two-dimensional (2D) semiconductor material, such as MoS₂, MoSe₂, WS₂, WSe₂, or SnS₂, or a nanostructure, such as nanodots, nanotubes, or graphene. The preliminary channel layer 46 may be formed to not completely fill the central region of the hole.

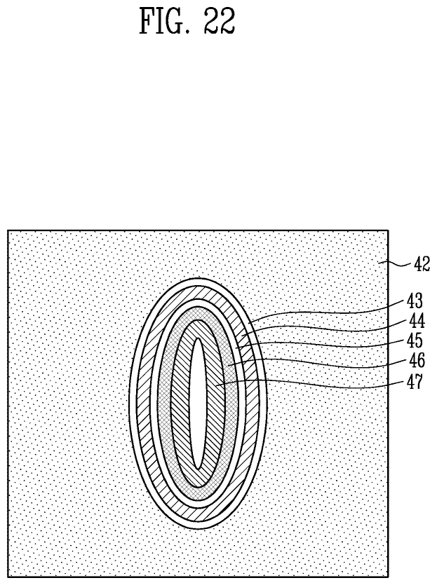

Referring to FIG. 22, a heat treatment (annealing) process on the preliminary channel layer 46 may be performed, and an oxide layer 47 may be formed by oxidizing an exposed inner wall of the preliminary channel layer 46. Accordingly, the thickness of the preliminary channel layer 46 may decrease.

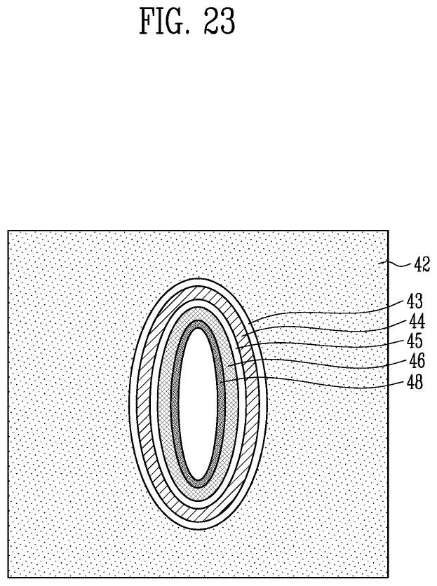

Referring to FIG. 23, the oxide layer (e.g., 47 of FIG. 22) may be removed by performing a strip process, and a sacrificial layer 48 may be formed by oxidizing the exposed inner wall of the preliminary channel layer 46. When the sacrificial layer 48 is formed through a deposition process, a portion of the sacrificial layer 48 corresponding to the uppermost portion of the hole may be formed to be relatively thick, and a portion of the sacrificial layer 48 corresponding to the bottom surface of the hole may be formed to be relatively thin, thus causing the thickness of the sacrificial layer 18 to be non-uniformly distributed. When the sacrificial layer 48 is formed through an oxidation process, the thicknesses of the sacrificial layer 48 corresponding to the uppermost portion and the bottom surface of the hole may be uniformly formed. Further, the sacrificial layer formed through the oxidation process may have fewer dangling bonds at an interface with the preliminary channel layer 46 than the sacrificial layer formed through the deposition process, thus exhibiting improved performance in terms of current flow and leakage current, for some embodiments. Furthermore, the sacrificial layer 48 formed through the oxidation process may have a higher etch selectivity with respect to the preliminary channel layer 46 than that of the sacrificial layer formed through the deposition process.

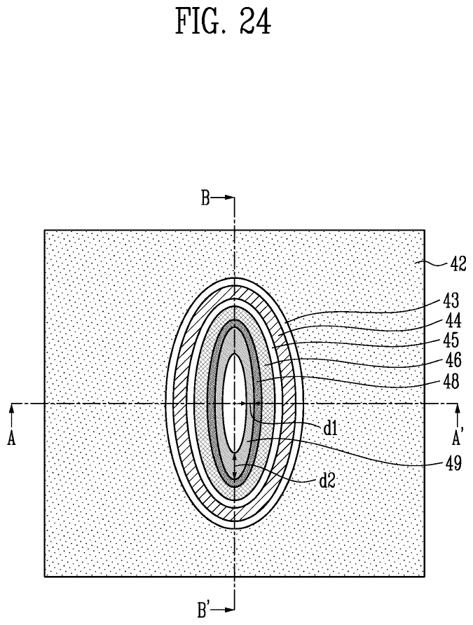

Referring to FIG. 24, a barrier layer 49 is formed along the inner wall of the sacrificial layer 48. The barrier layer 49 may include a polysilicon layer. The thickness d1 of the barrier layer 49 formed on the sidewall of the hole H in the first horizontal direction A-A′ and the thickness d2 of the barrier layer 49 formed on the sidewall of the hole H in the second horizontal direction B-B′ may be formed to be different from each other. For example, the thickness d1 of the barrier layer 49 formed on the sidewall of the hole H in the first horizontal direction A-A′ may be smaller than the thickness d2 of the barrier layer 49 formed on the sidewall of the hole H in the second horizontal direction B-B′.

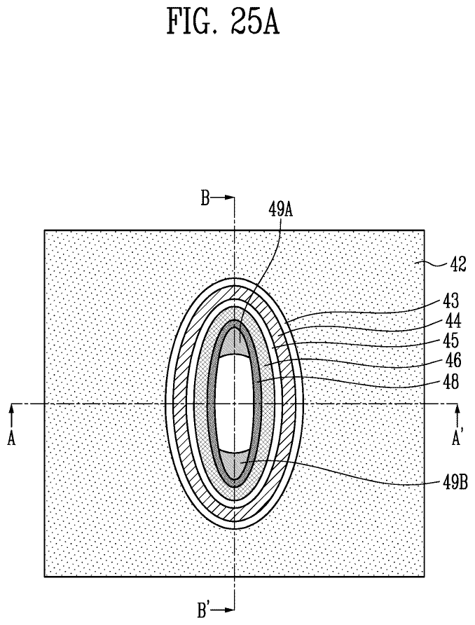

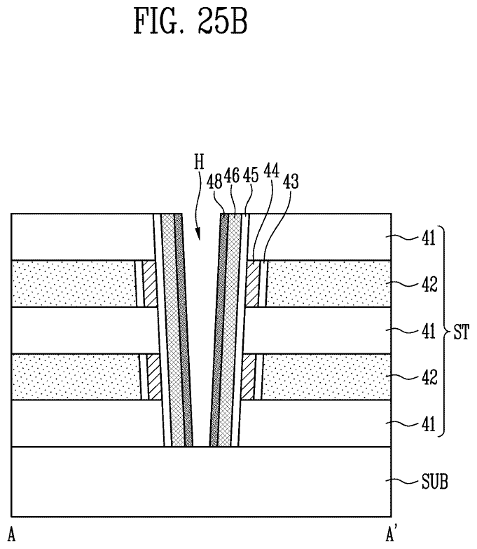

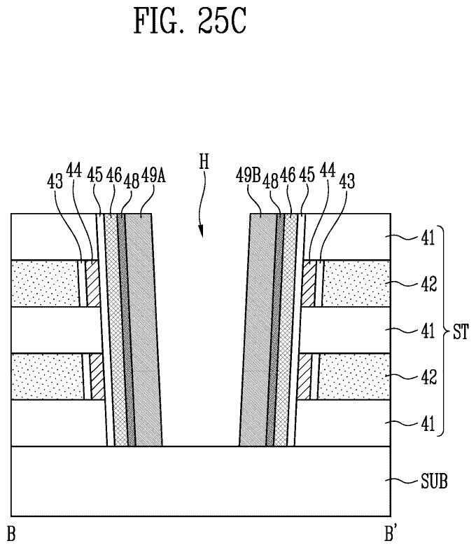

Referring to FIGS. 25A, 25B, and 25C, the barrier layer (e.g., 49 of FIG. 24) may be etched to a certain thickness by performing an etching process, and it may then be partially removed. The etching process may be performed using an isotropic etching process. For example, a portion of the barrier layer (e.g., 49 of FIG. 24) may be etched and removed such that the sidewall of the sacrificial layer 48 in the first horizontal direction A-A′ is exposed. During the etching process, the thickness of the barrier layer (e.g., 49 of FIG. 24) formed on the sidewall of the sacrificial layer 48 in the first horizontal direction A-A′ is smaller than the thickness of the barrier layer (e.g., 49 of FIG. 24) formed on the sidewall of the sacrificial layer 48 in the second horizontal direction B-B′, and thus the barrier layer (e.g., 49 of FIG. 24) may remain on the sidewall of the sacrificial layer 37 in the second horizontal direction B-B′ even if the barrier layer (e.g., 49 of FIG. 24) is etched to expose the sidewall of the sacrificial layer 48 in the first horizontal direction A-A′. The remaining barrier layer may be defined as the barrier patterns 49A and 49B. Also, during the isotropic etching process, due to differences in a surface area and a surface angle exposed to the etchant, an etching rate in the first horizontal direction A-A′ may be higher than an etching rate in the second horizontal direction B-B′. Due thereto, the barrier patterns 49A and 49B may be formed on opposite sidewalls of the hole H in the second horizontal direction B-B′. The horizontal cross-section of each of the barrier patterns 49A and 49B may have a crescent shape.

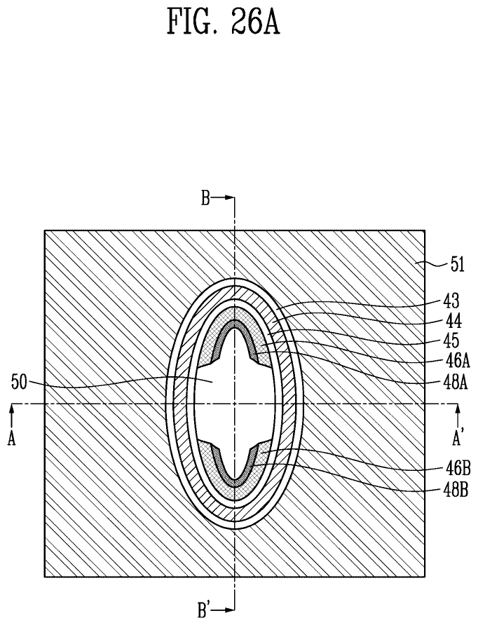

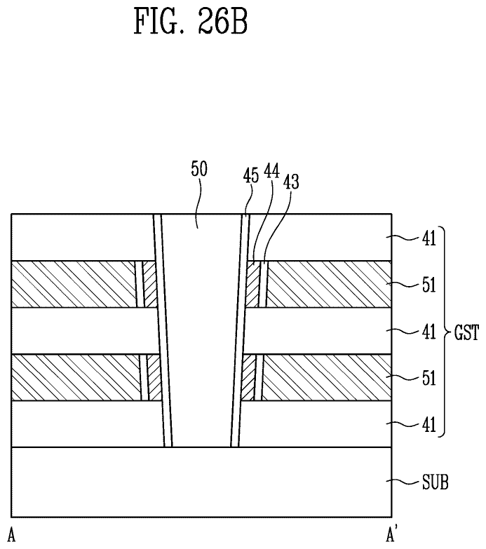

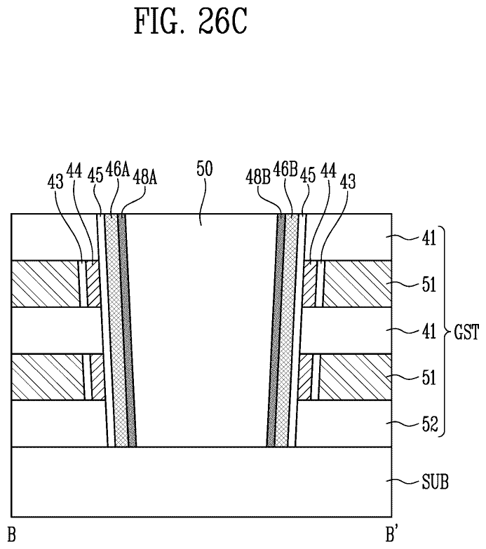

Referring to FIGS. 26A, 26B, and 26C, the sacrificial layer exposed by performing an etching process that uses the barrier patterns (e.g., 49A and 49B of FIGS. 25A, 25B, and 25C) as a mask may be partially etched, thus exposing the preliminary channel layer (e.g., 46 of FIGS. 25A, 25B, and 25C) in the first horizontal direction A-A′. Accordingly, the sacrificial layer may be patterned into a first sacrificial layer 48A and a second sacrificial layer 48B that are separated from each other. Thereafter, the preliminary channel layer (e.g., 46 of FIGS. 25A, 25B, and 25C) exposed by performing an etching process that uses the first sacrificial layer 48A and the second sacrificial layer 48B as a mask may be etched, thus exposing the tunnel insulating layer 45 in the first horizontal direction A-A′. Accordingly, the preliminary channel layer may be patterned into a first channel layer 46A and a second channel layer 46B that are separated from each other. Thereafter, the barrier patterns may be removed.

Thereafter, a core insulating layer 50 may be formed to fill the central region of the hole (e.g., H of FIGS. 25B and 25C). The core insulating layer 50 may contain an insulating material, such as an oxide.

Thereafter, an etching process may be performed to expose the sidewall of the stacked structure (e.g., ST of FIGS. 25B and 25C), and the exposed second material layers (e.g., 42 of FIGS. 25B and 25C) may be removed. Thereafter, in spaces from which the second material layers are removed, third material layers 51 may be formed. The third material layers 51 may contain a conductive material, such as polysilicon, tungsten, or metal. Due thereto, a gate stacked structure GST including the first material layers 41 and the third material layers 51 may be formed.

As described above, according to an embodiment of the present disclosure, the preliminary channel layer 46 and the sacrificial layer 48 may be formed through a DAO scheme including a deposition process, an annealing process, and an oxidation process, and thus the layer quality of the preliminary channel layer 46 and the sacrificial layer 48 may be improved, with the result that the channel current of the memory cell string may be increased, and leakage current may be reduced.

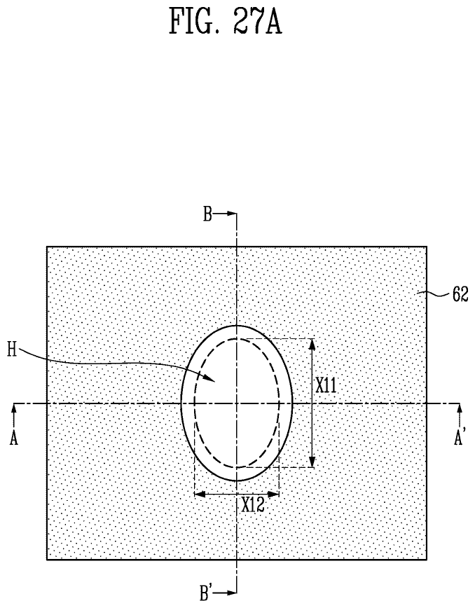

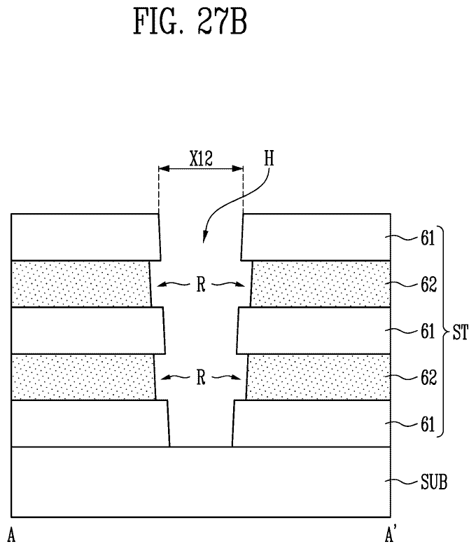

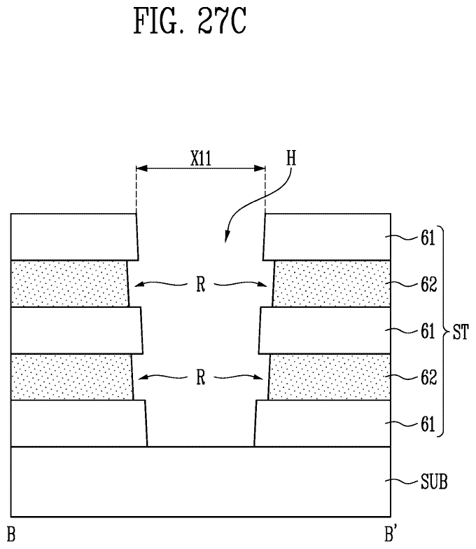

FIGS. 27A, 27B, 27C, 28A, 28B, 28C, 29, 30, 31, 32A, 32B, 32C, 33A, 33B, and 33C are plan views and sectional views for describing a method of manufacturing a semiconductor memory device according to an embodiment of the present disclosure.

Referring to FIGS. 27A, 27B, and 27C, a stacked structure ST is formed on a substrate SUB. The stacked structure ST may include first material layers 61 and second material layers 62 that are alternately stacked. The first and second material layers 61 and 62 may be stacked in a direction normal to the substrate SUB. The first and second material layers 61 and 62 may be formed using a deposition process, such as chemical vapor deposition (CVD).

The first material layers 61 may contain a material having a high etch selectivity with respect to the second material layers 62. In an example, the first material layers 61 may contain an insulating material, such as an oxide, and the second material layers 62 may contain a sacrificial material, such as a nitride. In an example, the first material layers 61 may contain an insulating material, such as an oxide, and the second material layers 62 may contain a conductive material, such as polysilicon or tungsten.

Also, a hard mask pattern (not illustrated) may be formed on the stacked structure ST, and a hole H passing through at least a portion of the stacked structure ST may be formed by performing an etching process that uses the hard mask pattern. The hole H may partially extend into the substrate SUB.

The hole H may be formed such that the width X12 of the hole H in a first horizontal direction A-A′ is smaller than the width X11 of the hole H in a second horizontal direction B-B′. For example, the cross-section of the hole H in the XY-plane may have an elliptical shape.

Thereafter, recess regions R may be formed by etching the sidewalls of the second material layers 62 exposed through the hole H to a recessed depth. For example, the sidewalls of the second material layers 62 may be etched to the recessed depth so that the first material layers 61 protrude beyond the second material layers 62 in the direction of the hole H. Due thereto, the sidewall of the hole H may be formed in a structure in which irregular portions (concave/convex portions) are sequentially arranged in the direction normal to the substrate SUB.

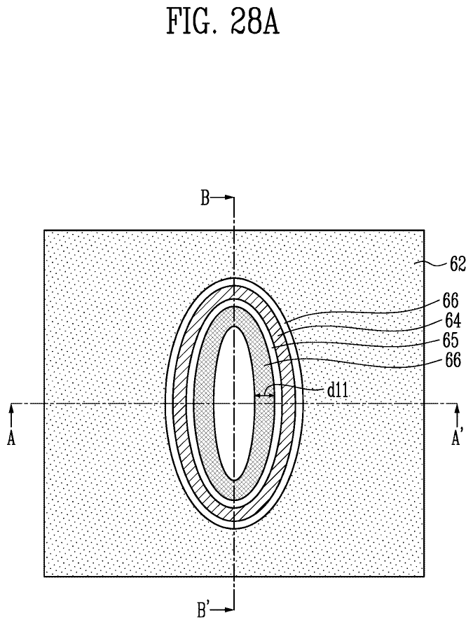

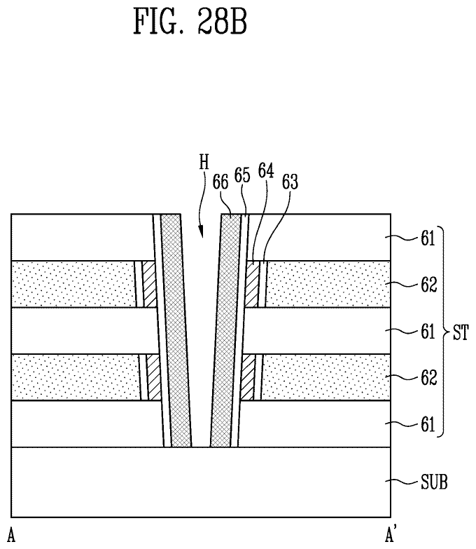

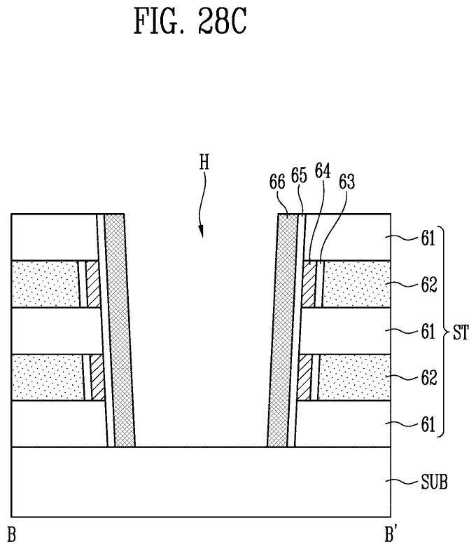

Referring to FIGS. 28A, 28B, and 28C, a blocking insulating layer 63 and a charge trap layer 64 are formed in each recess region (e.g., R of FIGS. 27B and 27C) of the hole H.

For example, the blocking insulating layer 63 and the charge trap layer 64 are sequentially formed along the sidewall of the hole H. Also, the blocking insulating layer 63 and the charge trap layer 64 may remain only in the recess regions (e.g., R of FIGS. 27B and 27C) by performing an etching process so that the sidewalls of the first material layers 61 are exposed.

Thereafter, a tunnel insulating layer 65 and a preliminary channel layer 66 are sequentially formed along the inner walls of the charge trap layer 64 and the sidewalls of the first material layers 61. The charge trap layer 64 may include a charge trap material, a nitride, a variable resistance material, a nanostructure, or a combination thereof. Thereafter, the tunnel insulating layer 65 may be formed along the inner wall of the charge trap layer 64. The tunnel insulating layer 65 may be a layer through which charges are tunneled by F-N tunneling or the like, and it may contain an insulating material, such as an oxide or nitride. Thereafter, the preliminary channel layer 66 may be formed along the inner wall of the tunnel insulating layer 65. The preliminary channel layer 66 may include a semiconductor material, such as silicon or germanium, may include an oxide semiconductor material, such as ZnO, In₂O₃, InZnO, ZnSnO, InGaZnO, or ZnGaSnO, a two-dimensional (2D) semiconductor material, such as MoS₂, MoSe₂, WS₂, WSe₂, or SnS₂, or a nanostructure, such as nanodots, nanotubes, or graphene. The preliminary channel layer 66 may be formed to not completely fill the central region of the hole. The preliminary channel layer 66 may be formed to have a first thickness d11. Thereafter, an annealing process may be performed on the preliminary channel layer 66.

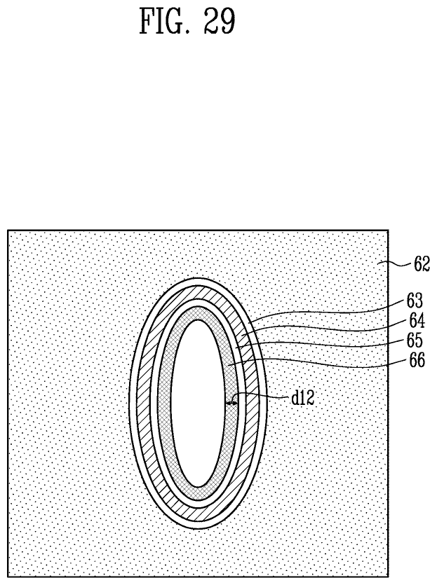

Referring to FIG. 29, an etching process may be performed such that the thickness of the preliminary channel layer 66 decreases. Accordingly, the preliminary channel layer 66 may be etched down to a second thickness d12.

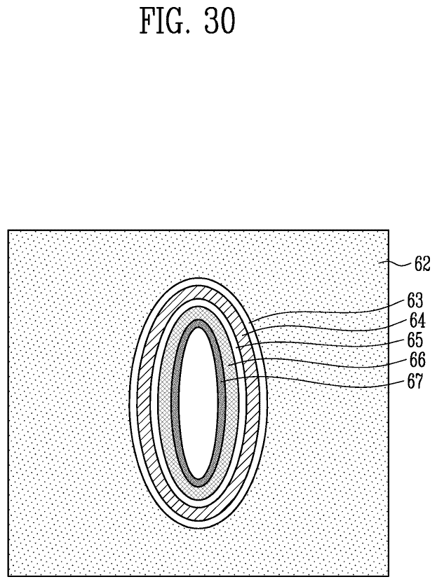

Referring to FIG. 30, a sacrificial layer 67 is formed by oxidizing the exposed inner wall of the preliminary channel layer 66. When the sacrificial layer 67 is formed through a deposition process, a portion of the sacrificial layer 67 corresponding to the uppermost portion of the hole may be formed to be relatively thick, and a portion of the sacrificial layer 67 corresponding to the bottom surface of the hole may be formed to be relatively thin, thus causing the thickness of the sacrificial layer 18 to be non-uniformly distributed. When the sacrificial layer 67 is formed through an oxidation process, the thicknesses of the sacrificial layer 67 corresponding to the uppermost portion and the bottom surface of the hole may be uniformly formed. Further, the sacrificial layer formed through the oxidation process may have fewer dangling bonds at an interface with the preliminary channel layer 66 than the sacrificial layer formed through the deposition process, thus exhibiting improved performance in terms of current flow and leakage current, for some embodiments. Furthermore, the sacrificial layer 67 formed through the oxidation process may have a higher etch selectivity with respect to the preliminary channel layer 66 than that of the sacrificial layer formed through the deposition process.

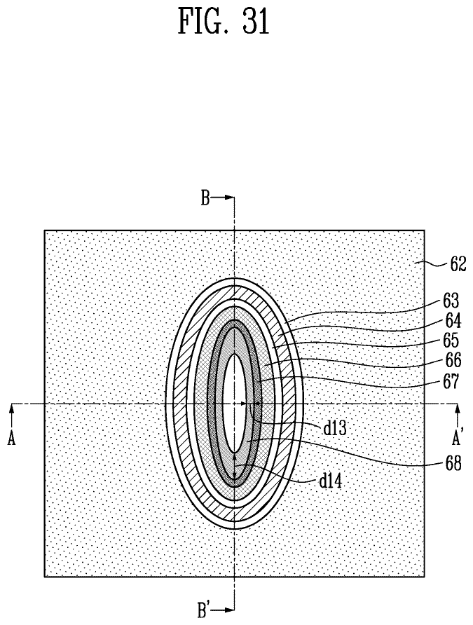

Referring to FIG. 31, a barrier layer 68 is formed along the inner wall of the sacrificial layer 67. The barrier layer 68 may include a polysilicon layer. The thickness d13 of the barrier layer 68 formed on the sidewall of the hole H in the first horizontal direction A-A′ and the thickness d14 of the barrier layer 68 formed on the sidewall of the hole H in the second horizontal direction B-B′ may be formed to be different from each other. For example, the thickness d13 of the barrier layer 68 formed on the sidewall of the hole H in the first horizontal direction A-A′ may be smaller than the thickness d14 of the barrier layer 68 formed on the sidewall of the hole H in the second horizontal direction B-B′.

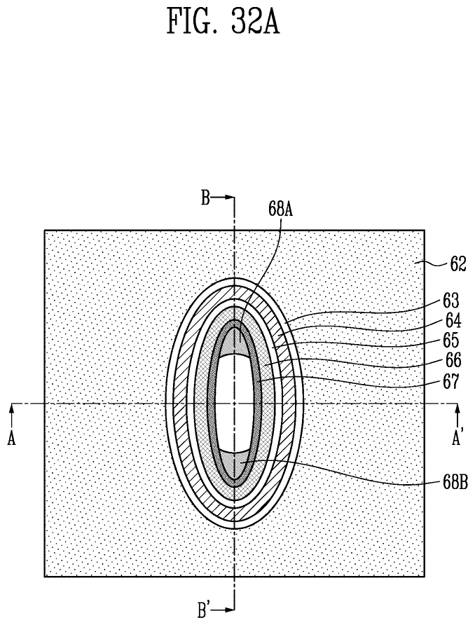

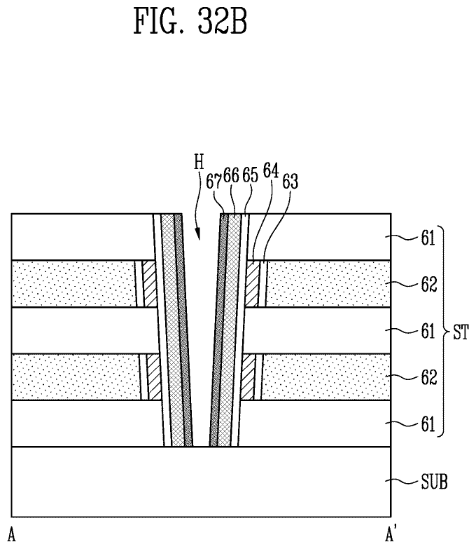

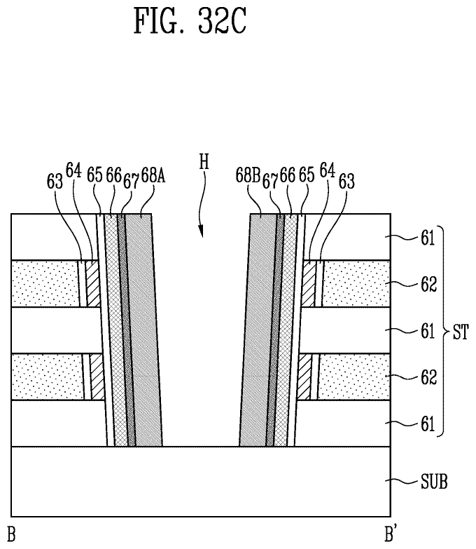

Referring to FIGS. 32A, 32B, and 32C, the barrier layer (e.g., 68 of FIG. 31) may be etched to a certain thickness by performing an etching process, and it may then be partially removed. The etching process may be performed using an isotropic etching process. For example, a portion of the barrier layer (e.g., 68 of FIG. 31) may be etched and removed such that the sidewall of the sacrificial layer 67 in the first horizontal direction A-A′ is exposed. During the etching process, the thickness of the barrier layer (e.g., 68 of FIG. 31) formed on the sidewall of the sacrificial layer 67 in the first horizontal direction A-A′ is smaller than the thickness of the barrier layer (e.g., 68 of FIG. 31) formed on the sidewall of the sacrificial layer 67 in the second horizontal direction B-B′, and thus the barrier layer (e.g., 68 of FIG. 31) may remain on the sidewall of the sacrificial layer 67 in the second horizontal direction B-B′ even if the barrier layer (e.g., 68 of FIG. 31) is etched to expose the sidewall of the sacrificial layer 67 in the first horizontal direction A-A′. The remaining barrier layer may be defined as the barrier patterns 68A and 68B. Also, during the isotropic etching process, due to differences in a surface area and a surface angle exposed to the etchant, an etching rate in the first horizontal direction A-A′ may be higher than an etching rate in the second horizontal direction B-B′. Due thereto, the barrier patterns 68A and 68B may be formed on opposite sidewalls of the hole H in the second horizontal direction B-B′. The horizontal cross-section of each of the barrier patterns 68A and 68B may have a crescent shape.

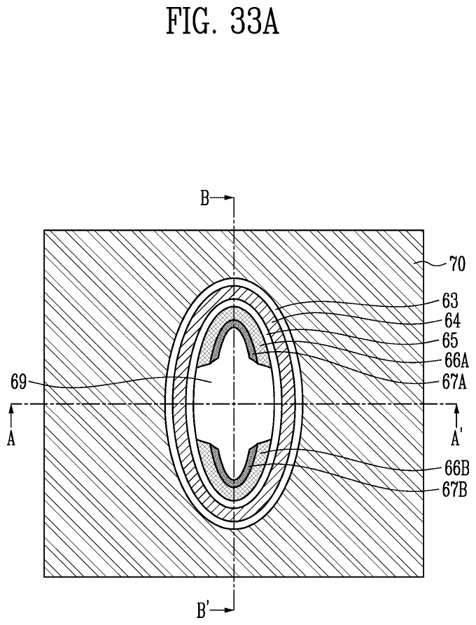

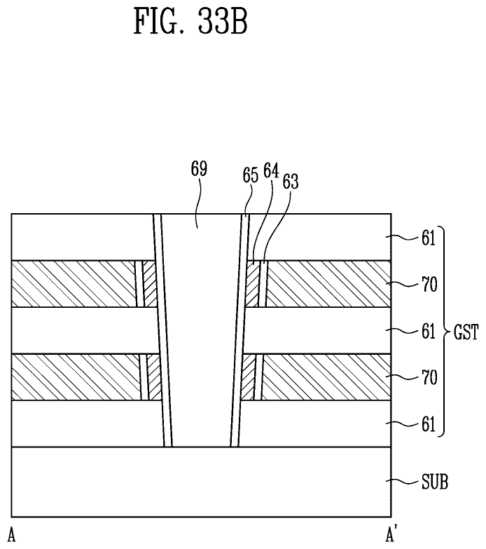

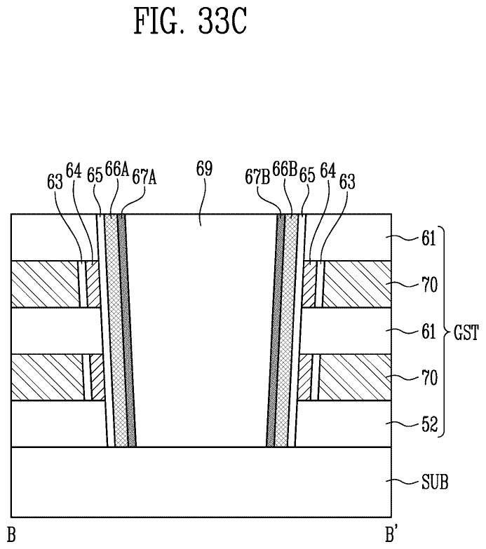

Referring to FIGS. 33A, 33B, and 33C, the sacrificial layer exposed by performing an etching process that uses the barrier patterns (e.g., 68A and 68B of FIGS. 32A, 32B and 32C) as a mask may be partially etched, thus exposing the preliminary channel layer (e.g., 66 of FIGS. 32A, 32B, and 32C) in the first horizontal direction A-A′. Accordingly, the sacrificial layer may be patterned into a first sacrificial layer 67A and a second sacrificial layer 67B that are separated from each other. Thereafter, the preliminary channel layer (e.g., 66 of FIGS. 32A, 32B, and 32C) exposed by performing an etching process that uses the first sacrificial layer 67A and the second sacrificial layer 67B as a mask may be etched, thus exposing the tunnel insulating layer 65 in the first horizontal direction A-A′. Accordingly, the preliminary channel layer may be patterned into a first channel layer 66A and a second channel layer 66B that are separated from each other. Thereafter, the barrier patterns may be removed.

Thereafter, a core insulating layer 69 may be formed to fill the central region of the hole (e.g., H of FIGS. 32A, 32B, and 32C). The core insulating layer 69 may contain an insulating material, such as an oxide.

Thereafter, an etching process may be performed to expose the sidewall of the stacked structure (e.g., ST of FIGS. 32A, 32B, and 32C), and the exposed second material layers (e.g., 62 of FIGS. 32A, 32B, and 32C) may be removed. Thereafter, in spaces from which the second material layers are removed, third material layers 70 may be formed. The third material layers 70 may contain a conductive material, such as polysilicon, tungsten, or metal. Due thereto, a gate stacked structure GST including the first material layers 61 and the third material layers 70 may be formed.

As described above, according to an embodiment of the present disclosure, the preliminary channel layer 66 and the sacrificial layer 67 may be formed through a DAO scheme including a deposition process, an annealing process, and an oxidation process, and thus the layer quality of the preliminary channel layer 66 and the sacrificial layer 67 may be improved, with the result that the channel current of the memory cell string may be increased, and leakage current may be reduced.

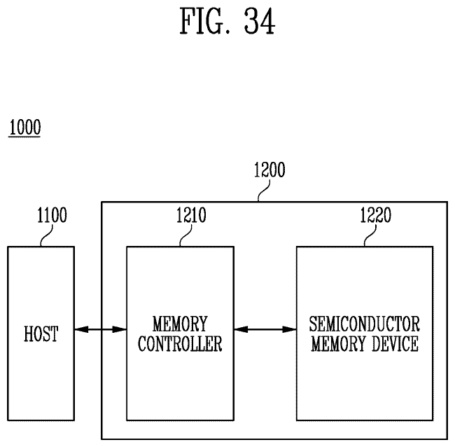

FIG. 34 is a block diagram illustrating a memory system including a semiconductor memory device according to an embodiment of the present disclosure.

Referring to FIG. 34, a memory system 1000 may include a host 1100 and a storage device 1200.

The host 1100 may store data in the storage device 1200 or may read data stored in the storage device 1200 based on an interface. The interface may include at least one of a double data rate (DDR) interface, a universal serial bus (USB) interface, a multimedia card (MMC) interface, an embedded MMC (eMMC) interface, a peripheral component interconnection (PCI) interface, a PCI-express (PCI-E) interface, an advanced technology attachment (ATA) interface, a serial-ATA (SATA) interface, a parallel-ATA (PATA) interface, a small computer system interface (SCSI), an enhanced small disk interface (ESDI), an integrated drive electronics (IDE) interface, a Firewire interface, a universal flash storage (UFS) interface, and a nonvolatile memory express (NVMe) interface.

The storage device 1200 may include a memory controller 1210 and a semiconductor memory device 1220. In an embodiment, the storage device 1200 may be a storage medium, such as a solid-state drive (SSD) or a universal serial bus (USB) memory device.

The memory controller 1210 may store data in the semiconductor memory device 1220 or read data stored in the semiconductor memory device 1220 under the control of the host 1100.

The semiconductor memory device 1220 may include one memory chip or a plurality of memory chips. The semiconductor memory device 1220 may store data or output stored data under the control of the memory controller 1210.

The teachings of the present disclosure may increase the number of memory cells by separating a channel layer in a plug hole into a plurality of channel layers. This may improve the layer quality of the channel layer by forming a sacrificial layer used as a mask layer based on a deposition-anneal-oxidation (DAO) method during an etching process for separating the channel layer.

What is claimed is:

1. A method of manufacturing a semiconductor memory device, comprising:
forming a hole passing through at least a portion of a stacked structure in which first material layers and second material layers are alternately stacked in a first direction;
forming a blocking insulating layer along the hole;
forming a charge trap layer along the blocking insulating layer;
forming a tunnel insulating layer along the charge trap layer;
forming a preliminary channel layer the tunnel insulating layer;
forming a sacrificial layer by oxidizing an exposed inner wall of the preliminary channel layer;
forming a first sacrificial layer and a second sacrificial layer that are separated from each other in a second direction crossing to the first direction by patterning the sacrificial layer; and
forming a first channel layer and a second channel layer by separating the preliminary channel layer in the second direction by performing an etching process.

2. The method according to claim 1, further comprising:
after forming the preliminary channel layer, oxidizing the inner wall of the preliminary channel layer; and
decreasing a thickness of the preliminary channel layer by striping a portion of the oxidized preliminary channel layer.

3. The method according to claim 1, further comprising:
after forming the preliminary channel layer, performing an annealing process over the preliminary channel layer.

4. The method according to claim 1, further comprising:
after forming the sacrificial layer, forming a barrier layer along the sacrificial layer.

5. The method according to claim 4, wherein forming the barrier layer comprises:
forming the barrier layer so that a thickness of the barrier layer in a third direction is less than a thickness of the barrier layer in the second direction, wherein the third direction is crossing to both the first and second directions.

6. The method according to claim 5, further comprising:
forming barrier patterns remaining at opposite ends of the barrier layer in the second direction by partially etching the barrier layer.

7. The method according to claim 6, wherein forming the first sacrificial layer and the second sacrificial layer comprises:
etching exposed portions of the sacrificial layer by using the barrier patterns as a mask.

8. The method according to claim 1, further comprising:
after forming the first channel layer and the second channel layer, filling a central portion of the hole with a core insulating layer; and
replacing the second material layers with conductive layers.

9. A method of manufacturing a semiconductor memory device, comprising:
forming a hole passing through at least a portion of a stacked structure in which first material layers and second material layers are alternately stacked in a first direction;
forming a blocking insulating layer along the hole;
forming a charge trap layer along the blocking insulating layer;
forming a tunnel insulating layer along the charge trap layer;
forming a preliminary channel layer along the tunnel insulating layer;
etching the preliminary channel layer to a decreased thickness;
forming a sacrificial layer by oxidizing an inner wall of the preliminary channel layer;
forming a first sacrificial layer and a second sacrificial layer that are separated from each other in a second direction crossing to the first direction by patterning the sacrificial layer; and
forming a first channel layer and a second channel layer by separating the preliminary channel layer in the second direction by performing an etching process.

10. The method according to claim 9, further comprising:
after forming the preliminary channel layer, performing an annealing process over the preliminary channel layer.

11. The method according to claim 9, further comprising:
after forming the sacrificial layer, forming a barrier layer along the sacrificial layer.

12. The method according to claim 11, wherein forming the barrier layer comprises:
forming the barrier layer so that a thickness of the barrier layer in a third direction is less than a thickness of the barrier layer in the second direction, wherein the third direction is crossing to both the first and second directions.

13. The method according to claim 12, further comprising:
forming barrier patterns remaining at opposite ends of the barrier layer in the second direction by partially etching the barrier layer.

14. The method according to claim 13, wherein forming the first sacrificial layer and the second sacrificial layer comprises:
etching exposed portions of the sacrificial layer by using the barrier patterns as a mask.

15. The method according to claim 9, further comprising:
after forming the first channel layer and the second channel layer, filling a central portion of the hole with a core insulating layer; and
replacing the second material layers with conductive layers.

16. A method of manufacturing a semiconductor memory device, comprising:
forming a hole passing through at least a portion of a stacked structure in which first material layers and second material layers are alternately stacked in a first direction;
forming recess regions by etching the second material layers through the hole to a recessed depth;
forming a blocking insulating layer and a charge trap layer in each of the recess regions;
forming a tunnel insulating layer along the first material layers and a sidewall of the charge trap layer;
forming a preliminary channel layer along the tunnel insulating layer;
forming a sacrificial layer by oxidizing an inner wall of the preliminary channel layer;
forming a first sacrificial layer and a second sacrificial layer that are separated from each other in a second direction crossing to the first direction by patterning the sacrificial layer; and
forming a first channel layer and a second channel layer by separating the preliminary channel layer in the second direction by performing an etching process.

17. The method according to claim 16, further comprising:
after forming the preliminary channel layer, oxidizing the inner wall of the preliminary channel layer; and
striping a portion of the oxidized preliminary channel layer to decrease a thickness of the preliminary channel layer.

18. The method according to claim 16, further comprising:
after forming the preliminary channel layer, performing an annealing process over the preliminary channel layer.

19. The method according to claim 16, further comprising:
after forming the sacrificial layer, forming a barrier layer along the sacrificial layer.

20. The method according to claim 19, wherein forming the barrier layer comprises:
forming the barrier layer so that a thickness of the barrier layer in a third direction is less than a thickness of the barrier layer in the second direction, wherein the third direction is crossing to both the first and second directions.

21. The method according to claim 20, further comprising:
forming barrier patterns remaining at opposite ends of the barrier layer in the second direction by partially etching the barrier layer.

22. The method according to claim 21, wherein forming the first sacrificial layer and the second sacrificial layer comprises:
etching portions of the sacrificial layer by using the barrier patterns as a mask.

23. The method according to claim 16, further comprises:
after forming the first channel layer and the second channel layer, filling a central portion of the hole with a core insulating layer; and
replacing the second material layers with conductive layers.

24. A method of manufacturing a semiconductor memory device, comprising:
forming a hole passing through at least a portion of a stacked structure in which first material layers and second material layers are alternately stacked in a first direction;
forming recess regions by etching the second material layers exposed through the hole to a recessed depth;
forming a blocking insulating layer and a charge trap layer in each of the recess regions;
forming a tunnel insulating layer along the first material layers and the charge trap layer;
forming a preliminary channel layer along the tunnel insulating layer;
etching the preliminary channel layer to decrease a thickness of the preliminary channel layer;
forming a sacrificial layer by oxidizing an exposed inner wall of the preliminary channel layer;
forming a first sacrificial layer and a second sacrificial layer that are separated from each other in a second direction orthogonal to the first direction by patterning the sacrificial layer; and
forming a first channel layer and a second channel layer by separating the preliminary channel layer in the second direction by performing an etching process.

25. The method according to claim 24, further comprising:
after forming the preliminary channel layer, performing an annealing process over the preliminary channel layer.

26. The method according to claim 25, further comprising:
after forming the sacrificial layer, forming a barrier layer along the sacrificial layer.

27. The method according to claim 26, wherein forming the barrier layer comprises:
forming the barrier layer so that a thickness of the barrier layer in a third direction is less than a thickness of the barrier layer in the second direction, wherein the third direction is crossing to both the first and second directions.

28. The method according to claim 27, further comprising:
forming barrier patterns remaining at opposite ends of the barrier layer in the second direction by partially etching the barrier layer.

29. The method according to claim 28, wherein forming the first sacrificial layer and the second sacrificial layer comprises:
etching exposed portions of the sacrificial layer by using the barrier patterns as a mask.

30. The method according to claim 24, further comprising:
after forming the first channel layer and the second channel layer, filling a central portion of the hole with a core insulating layer; and
replacing the second material layers with conductive layers.
